(19) United States
(12) Patent Application Publication
(10) Pub. No.: US 2024/0076543 A1
(43) Pub. Date: Mar. 7, 2024

(54) Weakly-Confined Semiconductor Nanocrystal, Preparation Method Therefor And Use Thereof

(71) Applicants: ZHEJIANG UNIVERSITY, Hangzhou (CN); Najing Technology Corporation Limited, Hangzhou (CN)

(72) Inventors: Xiaogang PENG, Hangzhou (CN); Liulin LYU, Hangzhou (CN); Jiongzhao LI, Hangzhou (CN); Shaojie LIU, Hangzhou (CN)

(21) Appl. No.: 18/241,994

(22) Filed: Sep. 4, 2023

(30) Foreign Application Priority Data
Sep. 5, 2022 (CN) 202211080221.5
Nov. 2, 2022 (CN) 202211363622.1

(51) Int. Cl. C09K 11/08; H01L 31/036

(52) U.S. Cl. CPC C09K 11/0811; H01L 31/036

(57) ABSTRACT

The present disclosure provides a weakly-confined semiconductor nanocrystal, a preparation method therefor and use thereof. A size of the nanocrystals is larger than an exciton diameter thereof; excitons in the nanocrystal are dynamic excitons, electron-hole Coulomb interaction of the dynamic excitons is insufficient to bind electrons and holes into stable bound excitons at operating temperatures, and the electrons and the holes of the dynamic excitons are constrained by boundaries of the nanocrystal. Since the excitons in the weakly-confined nanocrystals herein possess the characteristics of dynamic excitons, the nanocrystals herein possess unique optical and photoelectric properties distinct from conventional semiconductor nanomaterials. It holds unique value for applications requiring broad-spectrum emission (such as lighting) and significant importance for photovoltaic solar devices, photoelectric detectors, and photocatalysis.

### CROSS-REFERENCE TO RELATED APPLICATION

The application is provided on the basis of Chinese Application No. 202211080221.5, filed Sep. 5, 2022, which claims the benefit of priority to the Chinese Patent Application, which is incorporated by reference in its entirety herein.

### TECHNICAL FIELD

The present invention relates to the technical field of semiconductor nanocrystals, and in particular to a weakly-confined semiconductor nanocrystal, a preparation method therefor and use thereof.

### BACKGROUND

Since the emergence of semiconductor nanomaterials, the development of their synthesis chemistry has been one of the core topics. After decades of progress, significant advancements have been made in the synthesis of strongly-confined semiconductor nanomaterials, particularly in the aspects of morphology control, crystal form control, and size control. These materials not only achieve monodispersity in size and morphology but also exhibit monodispersity in their optical properties: achieving a photoluminescence quantum yield of 100%, mono-exponential decay of PL lifetime, no PL blinking, and ensemble photolumines cence peak width consistent with that of single particle. However, for traditional II-VI and III-V groups, most research has focused on strongly-confined small-sized semiconductor nanomaterials. The synthesis system of monodisperse small-sized semiconductor nanocrystals has been continuously improved, but achieving a controllable synthesis of monodisperse weakly-confined large-sized semiconductor nanomaterials remains challenging.

In bulk semiconductors, excitons are electron-hole pairs bound together by strong Coulomb interaction, which are produced when a semiconductor absorbs a photon. Additionally, electron-hole pairs can also be generated by electrical injection, as long as their Coulomb interaction significantly exceeds the thermal energy at a given temperature (approximately 25 meV at room temperature). Electron-hole pairs generated by electrical excitation in semiconductors can also form excitons.

Semiconductor nanocrystals with geometric sizes larger than the exciton diameter in bulk semiconductors are referred to as weakly-confined semiconductor nanocrystals. To date, there have been no reports on monodisperse II-IV and III-V group weakly-confined semiconductor nanocrystals in terms of size and morphology. Due to the inability to obtain high-quality samples, little is known about the properties of weakly-confined semiconductor nanocrystals.

In publicly available literature, the representative of weakly-confined nanocrystals is cuprous chloride (CuCl) nanocrystals, rather than the common stable II-IV and III-V group semiconductor nanocrystals. Currently, the theoretical models for weakly-confined semiconductor nanocrystals are also based on experimental facts related to CuCl. Specifically, due to the large exciton binding energy (˜233 meV) and exciton diameter less than 1 nm in CuCl, excitons in CuCl nanocrystals can stably exist at room temperature without ionizing into free electrons and holes (known as free carriers). Therefore, after excitation, the electronic structure of CuCl nanocrystals exhibits typical Wannier excitons (exciton energy levels similar to hydrogen atoms) and quantum confinement kinetic energy of the exciton center of mass, rather than being determined by the individual quantum confinement kinetic energies of Electrons and holes.

In recent years, another class of metal halide nanocrystals, namely cesium-lead halide perovskite (such as CsPbI₃) nanocrystals, has been studied. Due to their small exciton diameter and poor controllability of ion-type lattice growth, the resulting nanocrystals usually exceed their exciton diameter and can be classified as weakly-confined semiconductor nanocrystals. However, cesium-lead halide perovskite nanocrystals are ionic lattices with poor chemical, optical, and electrical stability. Thus, the unique properties of the currently disclosed weakly-confined semiconductor nanocrystals are limited, and their practicality presents significant challenges.

### SUMMARY

One purpose of the present invention is to provide a weakly-confined semiconductor nanocrystal, a preparation method therefor and use thereof.

To achieve the above purpose, the present invention provides a weakly-confined semiconductor nanocrystal, wherein a size of the nanocrystal is larger than an exciton diameter thereof, and the size of the nanocrystal is an average value of a diameter thereof or an average value of a length over centre of mass thereof; excitons in the nanocrystal are dynamic excitons, at operating temperatures, electron-hole Coulomb interaction of the dynamic excitons is insufficient to bind electrons and holes into stable bound excitons, the electrons and the holes of the dynamic excitons are constrained by boundaries of the nanocrystal, and the operating temperatures include room temperature.

According to another aspect of the present application, the present invention provides a weakly-confined semiconductor nanocrystal, wherein a size of the nanocrystal is larger than an exciton diameter thereof, and the size of the nanocrystal is an average value of a diameter thereof or an average value of a length over centre of mass thereof; under room temperature testing conditions, a UV-Visible absorption spectrum of the nanocrystal exhibits a quasi-continuous band absorption.

According to another aspect of the present application, the present invention provides a weakly-confined semiconductor nanocrystal, wherein a size of the nanocrystal is larger than an exciton diameter thereof, and the size of the nanocrystal is an average value of a diameter thereof or an average value of a length over centre of mass thereof; under room temperature testing conditions, a photoluminescence spectrum of the nanocrystal shows an asymmetric feature with a tailing towards higher energy.

According to another aspect of the present application, the present invention provides a weakly-confined semiconductor nanocrystal, wherein a size of the nanocrystal is larger than an exciton diameter thereof, and the size of the nanocrystal is an average value of a diameter thereof or an average value of a length over centre of mass thereof; under room temperature testing conditions, a double-Gaussian fitting result of PL emission spectra of the nanocrystal shows that the PL emission spectra of the nanocrystal contain two PL emission peak positions with different energies, that is, the nanocrystal possesses dual-level emission photoluminescence properties.

According to another aspect of the present application, the present invention provides a weakly-confined semiconductor nanocrystal, wherein a size of the nanocrystal is larger than an exciton diameter thereof, and the size of the nanocrystal is an average value of a diameter thereof or an average value of a length over centre of mass thereof; a biexcitonic photolumines cence quantum yield of the nanocrystal is not less than 50%.

Further, the biexcitonic photoluminescence quantum yield of the nanocrystal is not less than 70%, preferably not less than 80%, more preferably not less than 90%, and even more preferably not less than 95%.

Further, the size of the nanocrystal is 1 to 20 times the exciton diameter thereof, and preferably, the size of the nanocrystal is 1 to 6 times the exciton diameter thereof.

Further, the size of the nanocrystal is greater than 10 mm, preferably greater than 15 nm, more preferably greater than 20 nm, even more preferably greater than 25 nm, and most preferably greater than or equal to 30 nm.

Further, a relative standard deviation of size distribution of the nanocrystal does not exceed 10%, preferably not exceed 6%, more preferably not exceed 5%, even more preferably not exceed 4%, and most preferably not exceed 3%.

Further, the nanocrystal is either a core-structured nanocrystal or a core-shell structured nanocrystal.

Further, the nanocrystal is a cubic nanocrystal, a transmission electron microscope image shows that the nanocrystal has a square two-dimensional projection, and a high-resolution transmission electron microscope image shows that the nanocrystal has lattice hinges of single-period and dislocation-free and atomically smooth boundaries.

Further, the nanocrystal is a CdS or CdSe or CdSe/CdS core/shell cubic nanocrystal, a CdSe core size of the CdSe CdS core/shell cubic nanocrystal ranges from 6 mm to 25 mm, and a number of layers of CdS shell ranges from 1 to 20 monolayers.

Further, the nanocrystal is an II-IV group semiconductor or an III-V group semiconductor.

Further, the nanocrystal has a zinc-blende single-crystal structure.

Further, excitation spectra of the nanocrystal at different fluorescent emission positions substantially overlap.

Further, a PL emission peak position of the nanocrystal is substantially consistent with a bandgap width of a bulk material thereof.

Further, the photoluminescence full width at half maxima (FWHM) of the nanocrystal is greater than 70 meV.

Further, the single-particle photoluminescence of the nanocrystal shows no PL blinking for at least 1000 seconds.

The present application further provides a method for preparing a semiconductor nanocrystal, which includes the following steps:
synthesis of a nanocrystal seed: reacting a cationic precursor with a first fatty acid at a first temperature, and then adding a first anionic precursor for reacting to obtain a nanocrystal seed, a size of the nanocrystal seed being smaller than an exciton diameter thereof, and the size of the nanocrystal seed being an average value of a diameter thereof or an average value of a length over centre of mass thereof; and
growth of a nanocrystal: reacting a cationic precursor, a first fatty acid, a second fatty acid, and a fatty acid chloride at a second temperature, and then sequentially adding the nanocrystal seed and a second anionic precursor for growth to obtain a nanocrystal, a size of the nanocrystal being not less than an exciton diameter thereof, and the size of the nanocrystal being an average value of a diameter thereof or an average value of a length over centre of mass thereof.

Further, the cationic precursor is cadmium carboxylate, and the first anionic precursor is either a selenium (Se) precursor or a sulfur (S) precursor.

Further, the first fatty acid is a fatty acid with a carbon chain length of no less than 10, preferably a fatty acid with a carbon chain length of no more than 18.

Further, the second fatty acid is a fatty acid with a carbon chain length of no less than 22.

The weakly-confined semiconductor nanocrystal is used in illumination or display, photovoltaic solar devices, photoelectric detectors, lasers, quantum light sources, or photochemical catalysis.

### BRIEF DESCRIPTION OF THE DRAWINGS

The upper part of FIG. 1 shows the synthetic scheme for large-sized cubic nanocrystals of CdE (CdSe, CdS, CdSe/CdS core-shell); the lower part shows the TEM image of 30 nm CdSe cubic nanocrystals.

FIG. 2 shows the characterization results of 21 nm CdSe cubic nanocrystals: a wide-range TEM image (a), HRTEM images (b, c) with their corresponding FFT image (d), XRD spectrogram (e) normalized photoluminescence excitation spectra at different emission positions (f), and normalized UV-Visible absorption and PL emission spectra (g), wherein the inset in the TEM image (a) shows the statistical results of size distribution of nanocrystals.

FIG. 3 shows the characterization results of 21 nm CdS cubic nanocrystals: a wide-range TEM image (3), HRTEM images (b, c) with their corresponding FFT image (d), XRD spectrogram (e), normalized photoluminescence excitation spectra at different emission positions (f), and normalized UV-Visible absorption and PL emission spectra (g), wherein the inset in the TEM image (a) shows the statistical results of size distribution of nanocrystals.

FIG. 4 shows the characterization results of 20 nm CdSe8/CdS core-shell cubic nanocrystals: (a) TEM image with an inset showing the statistical results of the size distribution of nanocrystals; (b) element distribution map under STEM; (c, d) HRTEM images at different magnifications; (e) corresponding FFT image; (f) XRD spectrogram; (g) normalized photoluminescence excitation spectra at different emission positions; and (h) normalized UV-Visible absorption and PL emission spectra.

FIG. 5 shows the characterization results of 22 mm CdSe12/CdS core-shell cubic nanocrystals: (a) TEM image with an inset showing the statistical results of the size distribution of nanocrystals; (b) element distribution map under STEM; (c, d) HRTEM images at different magnifications; (e) corresponding FFT image; (f) XRD spectrogram; (g) normalized photoluminescence excitation spectra at different emission positions; and (h) normalized UV-Visible absorption and PL emission spectra.

FIG. 6 shows a comparison of the optical properties of different-sized CdSe cubic nanocrystals: (a) normalized UV-Visible absorption spectra/PL emission spectra. (b) PL emission peak positions, (c) photoluminescence full width at half maximum (FWHM), and (d) photoluminescence peak skewness. The inset in (b) shows the photoluminescence spectrum of 12 nm CdSe cubic nanocrystals, and the triangular data in (c) represents the photoluminescence FWHM of a single particle of the zinc-blende CdSe nanocrystals reported in the literature.

FIG. 7 shows a comparison of the optical properties of different-sized CdS cubic nanocrystals: (a) normalized UV-Visible absorption spectra/PL emission spectra, (b) PL emission peak positions, (e) photoluminescence FWHM, and (d) photoluminescence peak skewness.

FIG. 8 shows the normalized UV-Visible absorption spectra (a), PL emission spectra (b), transient photoluminescence spectra (c), PL emission peak positions and photoluminescence quantum yields (d), photoluminescence peak skewness and photoluminescence FWHM (e), as well as the variations of PL lifetimes and goodness of fit (f) with the CdS shell thickness of CdSe8/CdS cubic nanocrystals.

FIG. 9 shows the normalized UV-Visible absorption spectra (a), PL emission spectra (b), transient photoluminescence spectra (c), PL emission peak positions (d), photoluminescence peak skewness and photoluminescence FWHM (e), as well as the variations of PL lifetimes and goodness of fit (f) with the CdS shell thickness (ML) of CdSe12/CdS cubic nanocrystals. The inset in (d) shows the aggregate photoluminescence spectrum (dark line) and single-particle photoluminescence spectrum (light line) of CdSe12/20CdS cubic nanocrystals.

FIG. 10 shows the power-dependent PL emission spectra (a) and the variations of PL intensity with the excitation power (b) of 15 mm CdSe cubic nanocrystals; the inset in (a) shows the power-dependent normalized PL emission spectrum.

FIG. 11 shows the power-dependent PL emission spectra (a) and the variations of PL intensity with the excitation power (b) of CdSe8/20CdS cubic nanocrystals; the inset in (a) shows the power-dependent normalized PL emission spectrum; (c) shows the PL emission spectra of both aggregate and single-particle CdSe8/20CdS cubic nanocrystals, where the PL center peak and the PL intensity have been normalized; the upper graph of (d) shows the PL emission spectra of CdSe8/20CdS cubic nanocrystals along with the result from employing double-Gaussian fitting, and the lower graph shows the transient photoluminescence spectra of CdSe8/20CdS cubic nanocrystals at different emission positions.

FIG. 12 shows the temperature-dependent variations of PL lifetimes (a) and the relative rate of change in PL lifetimes (b) of CdSex/yCdS cubic nanocrystals.

FIG. 13 shows the time-dependent variations of single-particle PL Intensity of CdSe8/20CdS and CdSe12/20CdS cubic nanocrystals (a, c), as well as their respective single-particle photon second-order correlation curves and g₀⁽²⁾ values (b, d).

### DETAILED DESCRIPTION OF THE EMBODIMENTS

With reference to specific embodiments, further description of the present invention is provided below. It should be noted that, under non-conflicting circumstances, the various embodiments or the technical features described below may be arbitrarily combined to form new embodiments.

For clarity, the terms “substantially” or “approximately” are used herein to imply the possibility of variations in numerical values that are within acceptable ranges to those skilled in the art. According to one example, the terms “substantially” or “approximately” used herein should be interpreted to imply possible variations of up to 10% above or below any specified value. According to another example, the terms “substantially” or “approximately” used herein should be interpreted to imply possible variations of up to 5% above or below any specified value. According to yet another example, the terms “substantially” or “approximately” used herein should be interpreted to imply possible variations of up to 2.5% above or below any specified value.

The present application provides a weakly-confined semiconductor nanocrystal. The size of the nanocrystal is larger than the exciton diameter thereof; the excitons in the nanocrystal are dynamic excitons, the electron-hole Coulomb interaction of the dynamic excitons is insufficient to bind the electrons and holes into stable bound excitons at operating temperatures, and the electrons and holes of the dynamic excitons are constrained by the boundaries of the nanocrystal. The aforementioned operating temperature includes room temperature. In some embodiments, the aforementioned operating temperature is not lower than room temperature.

In the present application, the size of the nanocrystal is larger than the exciton diameter thereof, making it a weakly-confined semiconductor nanocrystal. The term “size of the nanocrystal” herein refers to the average value of the diameter or the length over the centre of mass of the nanocrystal.

When a semiconductor material is excited with energy greater than bandgap thereof, electrons in the valence band are excited to the conduction band, leaving behind a hole in the valence band. The Coulomb interaction between the electrons and holes causes them to form an electron-hole pair within a certain spatial region, resembling the structure of a hydrogen atom. The electron-hole pair is also referred to as an “exciton”. The size of the exciton can be described by the exciton Bohr radius, and the “exciton diameter” mentioned herein is twice the exciton Bohr radius. In bulk semiconductor materials, the exciton radius is a fixed value. For example, the exciton Bohr radius of CdS is 2.8 nm (thus, the exciton diameter is 5.6 nm), and the exciton Bohr radius of CdSe is 5.6 nm (thus, the exciton diameter is 11.2 nm).

In the present application, the electronic structure of the nanocrystals is studied mainly by using spectroscopic methods, so that the energy level structure of the nanocrystals is determined. Experimental findings indicate that the exciton energy level structure based on CuCl is not applicable to the nanocrystals described in the present application under normal temperature conditions. Taking the nanocrystals of the II-IV and III-V groups as examples, the excitons thereof have very small binding energies, and at common temperatures, excitons in weakly-confined nanocrystals cannot exist stably; instead, they are in an ionized state. However, the ionized electrons and holes are constrained by the boundaries of the nanocrystals and do not significantly escape into the environmental medium outside the nanocrystals. This leads to the kinetic energies of the ionized electrons and holes being determined by the size of the boundaries, and significantly greater than the exciton binding energy of bulk semiconductors. As a result, such an energy level structure does not conform to the suggested weakly-confined nanocrystal model based on CuCl in the literature, but is mainly determined by the confinement kinetic energies of free electrons and holes. The electron-hole Coulomb interaction resulting from spatial confinement is suitable to be treated as a perturbation term in calculations.

Generally, excitons in solids can be classified into two types: The first type is called bound excitons or Frenkel excitons. In materials with low dielectric constants, such as ionic crystals, the excited electrons and holes are tightly bound together in the same or nearest neighboring unit cells, with typical binding energies ranging from 0.1 eV to 1 eV. The second type is known as Wannier excitons, which exist in materials with higher dielectric constants. In such materials, the electric-field screening within the crystal reduces the Coulomb interaction between electrons and holes, resulting in excitons with much larger radii than the unit cell size of the lattice. Consequently, the influence of the lattice potential on the effective masses of electrons and holes needs to be considered. Due to the lower effective masses and screened Coulomb interactions, the binding energy of Wannier excitons is typically significantly less than 0.01 eV.

However, the excitons in the nanocrystals described in the present application are distinct from the traditional two types of excitons, and are referred to as dynamic excitons. The electron-hole Coulomb interaction of the dynamic excitons herein is insufficient to bind the electrons and holes into stable bound excitons at operating temperatures; instead, they are in an ionized state. Moreover, the ionized electrons and holes are constrained by the boundaries of the nanocrystals and cannot significantly escape into the environmental medium outside the nanocrystals.

Since the excitons in the nanocrystals herein possess the characteristics of dynamic excitons, the nanocrystals possess unique optical and photoelectric properties distinct from conventional semiconductor nanomaterials. For example, the electrons (or holes) of the dynamic excitons have a high density of band-edge states and a small intra-band energy gap, resulting in rare double-peak and steady-state emission at room temperature. This holds unique value for applications requiring broad-spectrum emission (such as lighting). For another example, the electron (or hole) wave functions of dynamic excitons have a weak mutual constraint which rapidly diminishes with increasing temperature, facilitating the electron-hole transfer. This holds significant importance for photovoltaic solar devices, photoelectric detectors, and photocatalysis.

Furthermore, the wave functions of dynamic excitons in the nanocrystals are distant from irregular surfaces and are confined to the interior of the lattice. Under low-temperature conditions, dynamic excitons in the nanocrystals possess good determinism, characterized by ultra-narrow photoluminescence FWHM and lifetime-determined narrow peak emissions at low temperatures (<10 K). This photoluminescence FWHM is much narrower than that of strongly-confined nanocrystals of the same material, making it suitable for the development of quantum light sources.

Experiments further demonstrate that when the dynamic excitons in the nanocrystals contain more than two free carriers, the multiple wave functions of carriers of the same charge (electrons or holes) have sufficient free delocalization to overlap very little with each other, resulting in a small Auger effect in the nanocrystals of the present application. In this regard, the charge states of the weakly-confined nanocrystals of the II-IV and Ill-V groups can still guarantee nearly perfect single-exciton and multi-exciton luminescence quantum yields. Under strong excitation conditions, whether in luminescence, photovoltaics, lasers, or photochemical applications, the biexciton or multi-exciton states of the weakly-confined nanocrystals of the II-IV and III-V groups can guarantee high quantum yields.

In some embodiments, the size of the nanocrystal is 1 to 20 times the exciton diameter thereof. Preferably, the size of the nanocrystal is 1 to 6 times the exciton diameter thereof. For example, CdSe has an exciton diameter of 11.2 mm, and CdSe cubic crystals are prepared herein with a size ranging from 10-30 mm; CdS has an exciton diameter of 5.6 mm, and CdS cubic crystals are prepared herein with a size ranging from 7-21 nm. Alternatively, the size of the nanocrystal is 2 to 6 times the exciton diameter thereof.

In some embodiments, the size of the nanocrystal is greater than 10 nm, preferably greater than 15 nm, more preferably greater than 20 nm, even more preferably greater than 25 mm, and most preferably greater than or equal to 30 nm.

In some embodiments, the nanocrystals are monodisperse nanocrystals. The present application provides a method for preparing nanocrystals that enables controlled growth of nanocrystal size and morphology, synthesizing monodisperse, and large-sized nanocrystals. The term “monodisperse” as used herein refers to nanocrystals with uniform size and morphology and possessing good dispersibility in a specific medium.

In some embodiments, the relative standard deviation of the size distribution of the nanocrystal does not exceed 10%, preferably not exceed 6%, more preferably not exceed 5%, even more preferably not exceed 4% and most preferably not exceed 3%. A lower relative standard deviation indicates that the nanocrystals possess good size and morphology monodispersity.

In some embodiments, the transmission electron microscope image shows that the nanocrystals have a uniform and regular square two-dimensional projection. That is, the nanocrystals possess good morphology monodispersity.

In some embodiments, the high-resolution transmission electron microscope image shows that the nanocrystals have lattice fringes of single-period and dislocation-free and atomically smooth boundaries. The clear lattice fringes of single-period and dislocation-free indicate that the nanocrystals possess good single-crystalline nature. The atomically smooth boundaries indicate good smoothness of the nanocrystal faces, namely good integrity of their morphology.

In some embodiments, the excitation spectra of the nanocrystal at different fluorescent emission positions substantially overlap. Generally, only when nanocrystal size is monodisperse, the corresponding excitonic states of the nanocrystals are monodisperse, and the photoluminescence contributions from different emission peaks in the photoluminescence spectra originate from the same nanoparticle, thus the excitation spectra at different emission positions of the nanocrystals are identical. This indicates that the nanocrystals possess good size monodispersity, and the size distribution thereof does not affect the exciton energy level structure of the nanocrystals.

In some embodiments, the nanocrystal has a zinc-blende single-crystal structure. According to the XRD characterization results, the prepared nanocrystals herein are of a pure zinc-blende structure without obvious defects.

In some embodiments, under room temperature testing conditions, the UV-Visible absorption spectra of the nanocrystals do not show clearly distinguishable exciton absorption peaks. Instead, they exhibit bulk-like quasi-continuous band absorption. The nanocrystals herein exhibit a relatively weak quantum confinement effect, showing bulk-like absorption properties.

In some embodiments, under room temperature testing conditions, the photoluminescence spectra of the nanocrystals show an asymmetric feature; specifically, the photoluminescence spectra of the nanocrystals show an asymmetric feature with a tailing towards higher energy. The asymmetric feature of the photoluminescence spectra of the nanocrystals leads to a relatively wide FWHM of the photoluminescence spectra of the nanocrystals.

In some embodiments, the intrinsic photoluminescence FWHM of the monodispersed nanocrystals is greater than 70 meV.

In some embodiments, under room temperature testing conditions, the double-Gaussian fitting result of the PL emission spectra of the nanocrystals shows that the PL emission spectra of the nanocrystals contain two PL emission peak positions with different energies, that is, the nanocrystals possess dual-level emission photoluminescence properties.

In some embodiments, the PL emission peak position of the nanocrystal is substantially consistent with the bandgap width of the bulk material thereof. The nanocrystals herein exhibit a relatively weak quantum confinement effect, so the spectral property thereof is very similar to that of bulk materials. For example, the PL emission peak position of the CdS nanocrystals prepared herein with a size of 21 mm reaches 2.38 eV, which is consistent with the bandgap width of 2.38 eV (300 K) for bulk zinc-blende CdS reported in the literature.

In some embodiments, the single-particle photolumines cence of the nanocrystals shows no PL blinking for at least 1000 s.

In some embodiments, the biexcitonic photoluminescence yield of the nanocrystals is not less than 500%, preferably not less than 70%, more preferably not less than 80%, even more preferably not less than 90%, and most preferably not less than 95%.

In some embodiments, the nanocrystal is either a core-structured nanocrystal or a core-shell structured nanocrystal.

In some embodiments, the nanocrystal is an II-IV group semiconductor or an III-V group semiconductor, such as telluride, selenide, sulfide, phosphide, and arsenide semiconductors.

In some embodiments, the nanocrystal is a CdS or CdSe or CdSe/CdS core shell cubic nanocrystal.

In some embodiments, the CdSe core size of the CdSe CdS core shell cubic nanocrystal ranges from 6 nm to 25 nm, and the number of layers of CdS shell ranges from 1 to 20 monolayers.

The weakly-confined CdE (CdS or CdSe or CdSe/CdS core/shell) cubic nanocrystals herein possess excellent optical emission properties. For example, the weakly-confined CdSe/CdS core/shell nanocrystals exhibit a nearly 100% biexciton emission efficiency, no PL blinking in single particles, and complete spectral overlap between the aggregate and single-particle photoluminescence spectra. Furthermore, CdE cubic nanocrystals further exhibit unique size-dependent intrinsic optical properties. For example, as the nanocrystal size increases, the photoluminescence FWHM of the CdE does not decrease gradually but rather decrease first, then increase rapidly, and then decrease again. Furthermore, when the CdE cubic nanocrystals reach a critical size, their corresponding absorption spectra transition to bulk-like quasi-continuous band absorption, with an asymmetric tailing in the photoluminescence spectra towards higher energy. Moreover, when the CdSe CdS core shell cubic nanocrystals are larger than their corresponding critical size, their corresponding photoluminescence peak shifts towards higher energy and their PL lifetime experiences a rapid increase, which is an anomalous phenomenon. It is worth noting that the critical size for different nanocrystals is close to their corresponding exciton Bohr diameter.

Through theoretical calculations of the energy level structure of CdE cubic nanocrystals and fitting of corresponding nanocrystal photoluminescence and absorption spectra, the correlation between the band-edge energy level structure and the optical property of the weakly-confined CdE cubic nanocrystals is revealed. As the nanocrystal size increases, the density of band-edge states gradually increases, and therefore the exciton absorption peak features in the absorption spectra fade into a quasi-continuous band absorption. Furthermore, the higher density of states enables the simultaneous emission of two energy levels during the fluorescent emission at room temperature, leading to an asymmetric PL emission spectrum and a rapid increase in the photoluminescence FWHM.

Size-dependent and temperature-dependent experiments were conducted to analyze the exciton decay properties of CdSe CdS core shell cubic nanocrystals. The experimental results indicate that the decay rate of excitons is influenced not only by the strength of electron confinement effect but also by the strength of hole confinement effect. Moreover, different confinement effects lead to varying temperature-dependent lifetime change rates in CdSe/CdS core shell cubic nanocrystals.

The CdSe12/20CdS (12 nm CdSe as core growing with 20 monolayers of CdS) cubic nanocrystals prepared herein exhibit a high biexciton efficiency of up to 99%, indicating minimal Auger effect in multi-exciton processes. This makes them an ideal material for high-power devices such as light-emitting diodes and lasers.

Preliminary experimental results indicate that cubic nanocrystals are easier to self-assemble into densely packed superlattices, which will also effectively enhance interparticle conductivity. By tuning the composition of II-VI group semiconductor nanocrystals, their PL emission position can reach the standard positions for green and red light. As a result, weakly-confined core/shell cubic nanocrystals have distinct advantages for practical applications in high-power devices.

Preliminary experimental results indicate that the room temperature photoluminescence FWHM exceeding 70 meV of weakly-confined CdSe8/20CdS cubic nanocrystals is reduced to 30 μeV (the lowest detector resolution) at low temperatures. The linear PL emission implies that at low temperatures, the emission photon purity of weakly-confined CdSe8/20CdS cubic nanocrystals substantially meets the requirements for single-photon devices.

The present application provides a method for preparing a semiconductor nanocrystal, which includes the following steps:
synthesis of a nanocrystal seed: reacting the cationic precursor with the first fatty acid at the first temperature, and then adding the first anionic precursor for reacting to obtain a nanocrystal seed, a size of the nanocrystal seed being smaller than the exciton diameter thereof, and
growth of a nanocrystal: reacting the cationic precursor, the first fatty acid, the second fatty acid, and the fatty acid chloride at the second temperature, and then sequentially adding the nanocrystal seed and the second anionic precursor for growth to obtain a nanocrystal with a size larger than the exciton diameter.

The synthesis of the weakly-confined nanocrystal adopts a two-step growth synthesis strategy involving separate nucleation and growth stages. According to the preparation method of the present application, the introduction of fatty acid chloride during the growth step of the nanocrystals is due to the favorable impact of chloride ions on the synthesis of cubic nanocrystals. Considering the strong binding energy between chloride ions and cadmium ions, introducing chloride ions during the nucleation stage is disadvantageous; therefore, no acyl chlorides are added in the synthesis step of the nanocrystal seed.

In some embodiments, the second reaction temperature is higher than the first reaction temperature.

In some embodiments, the cationic precursor is cadmium carboxylate, and the first anionic precursor is either a selenium (Se) precursor or a sulfur (S) precursor.

Further, the first fatty acid is a fatty acid with a carbon chain length of no less than 10, preferably a fatty acid with a carbon chain length of no more than 18.

Further, the second fatty acid is a fatty acid with a carbon chain length of no less than 22.

The present application further provides use of the nanocrystal in illumination, photovoltaic solar devices, photoelectric detectors, lasers, or quantum light sources.

### Embodiment

(1) Preparation of Reaction Precursor

0.1 M (mol/L) selenium powder-ODE suspension (Se-SUS): 1 mmol of selenium powder (0.079 g) was weighed and placed into a 20 mL glass vial, and 10 mL of octadecene (ODE) solution was added; the mixture was sonicated for 5 min and then shaken to obtain a 0.1 M Se-SUS suspension. Similar steps could be used to prepare Se-SUS suspensions of other concentrations, commonly used concentrations being 0.025 M. 0.1 M, and 0.2 M.

0.1 M (mol/L) selenium powder-ODE solution (Se-ODE): 3 mmol of selenium powder (0.237 g) was weighed and placed into a 20 mL glass vial, and 5 mL of ODE solution was added; the mixture was sonicated for 5 min. Another 25 mL of octadecene solution was taken and added to a 50 mL three-necked flask and heated to 250° C. After shaken up, the selenium powder suspension was injected in five portions at a rate of 1 mL per time into the three-necked flask. Once all the selenium powder was added into the three-necked flask, the reaction temperature was lowered to 200° C. and maintained for 4 hours before stopping the reaction.

0.1 M (mol/L) sulfur powder-ODE solution (S-ODE): 1.5 mmol of sulfur powder (0.048 g) was weighed and placed into a 20 mL glass vial, and 15 mL of ODE solution was added; the mixture was sonicated until the sulfur powder was completely dissolved to obtain a 0.1 M S-ODE solution. Similar steps could be used to prepare S-ODE solutions of other concentrations, commonly used concentrations being 0.1 M and 0.2 M. The S-ODE stock solution should also be stored away from light.

0.1 M (mol/L) octadecanoyl chloride stock solution: 1 mmol of octadecanoyl chloride (0.309 g) was weighed and placed into a 20 mL glass vial, and 10 mL of ODE solution was added; the mixture was shaken up to obtain a 0.1 M octadecanoyl chloride solution.

0.1 M (mol/L) cadmium carboxylate solution: 0.4 mmol of cadmium acetate dihydrate (0.106 g). 0.6 mmol of oleic acid (erucic acid), 0.6 mmol of decanoic acid, and 4 mL of ODE solution were weighed and placed into a 25 mL three-necked flask; the flask was purged with argon gas and heated to 150° C., and the temperature was maintained for 30 min.

0.1 M (mol/L) cadmium carboxylate chloride solution: 0.2 mmol of cadmium acetate dihydrate (0.054 g), 0.6 mmol of oleic acid (erucic acid), 0.4 mmol of decanoic acid, and 2 mL of ODE solution were weighed and placed into a 10 mL three-necked flask; the flask was purged with argon gas and heated to 150° C., and the temperature was maintained for 10 min, and then further increased to 270° C.; 0.4 mL of octadecanyl chloride stock solution (0.04 mmol of acyl chloride) was injected, and the reaction temperature was maintained at 270° C. for 10 min, and finally lowered to 100° C. for later use. Note: For the preparation of large-sized nanocrystals, oleic acid was replaced with an equivalent amount of erucic acid, and the prepared cadmium carboxylate chloride salt should be used on the same day.

(2) Synthesis of CdSe and CdS Nanocrystal Seeds

Synthesis of CdSe nanocrystal seeds: 0.2 mmol of cadmium acetate dihydrate, 4 mmol of stearic acid, 12 mmol of oleic acid, and 28 mL of ODE solution were added into a 50 mL three-necked flask; the flask was purged with argon gas and heated to 150° C., the temperature was maintained for 10 min, and then further increased to 250° C., and 1 mL of 0.1 M Se-SUS suspension was rapidly injected. After 5 min of reaction, 0.1 mL of a 0.1 M Se-SUS suspension was injected every 5 min. During the reaction process, a small portion of the reaction solution was added to a cuvette containing toluene. Then a UV-Visible absorption or PL emission spectral test was performed to monitor the progress of the reaction. Approximately five additional injections of Se-SUS were carried out (about 30 min total), and the first exciton absorption peak of the CdSe nanocrystal seeds reached 550 nm (PL emission peak position at approximately 560 nm, with a nanocrystal size of about 3 nm). At this point, the heating apparatus was removed, and the temperature was lowered to below 100° C. to stop the reaction.

Synthesis of CdS nanocrystal seeds: 0.2 mmol of cadmium oxide, 3 mmol of oleic acid, and 6 mL of ODE solution were placed into a 25 mL three-necked flask; the flask was purged with argon gas and heated to 260° C. until the solution became completely clear. The temperature was then lowered to 230° ° C., and 0.5 mL of 0.1 M S-ODE solution was added. During the reaction process, a small portion of the reaction solution was added to a cuvette containing toluene. Then a UV-Visible absorption or PL Emission spectral test was performed to monitor the progress of the reaction. After 15 min of reaction, the first exciton absorption peak of the CdS nanocrystal seeds reached 430 nm (PL emission peak position at 442 nm, with a size of about 3 nm). At this point, the heating apparatus was removed, and the temperature was lowered to below 100° C. to stop the reaction.

(3) Synthesis of CdSe Cubic Nanocrystals

Synthesis of CdSe cubic nanocrystals with a typical size smaller than 10 nm: 0.2 mmol of cadmium acetate dihydrate, 1.2 mmol of oleic acid, and 10 mL of ODE solution were placed into a 25 mL three-necked flask; the flask was purged with argon gas and heated to 150° C., and the temperature was maintained for 10 min, and then further increased to 270° C., and 0.4 mL of 0.1 M octadecanoyl chloride stock solution was added. After 5 min of reaction, purified CdSe nanocrystal seeds (70 nmol) were added to the mixture. 0.03 M Se-ODE precursor solution was added dropwise to the mixture at a rate of 1.2 mL/h until the CdSe cubic nanocrystals reached the desired size. The heating and the dropwise addition of the Se precursor were stopped to stop the reaction. After approximately 4 hours of dropwise addition of Se-ODE, the first exciton absorption peak of the UV-Visible absorption spectrum of the CdSe cubic nanocrystals reached 690 nm (PL emission spectrum peak at 695 nm, with a size of about 8 nm). During the reaction process, a certain amount of the reaction solution (˜250 μL) was added to a cuvette containing a certain amount of toluene (2 mL) for UV-Visible absorption and PL emission spectral measurements to monitor the progress of the reaction. Regular quantified sampling was performed for quantitative UV-Visible absorption and PL emission spectral measurements. Note: When the size of the CdSe cubic nanocrystals exceeded 8 nm, it was necessary to add a certain amount of decanoic acid to form an entropy ligand system to maintain the solution stability of the CdSe cubic nanocrystal. The optimal molar ratio of oleic acid to decanoic acid was between 4:1 and 2:1. Furthermore, after the reaction was completed, the solution temperature was lowered to 150° C., then 1 mmol of oleic acid was added, and the temperature was maintained at 150° C. for 10 min. This is done to reduce the solubility of the CdSe cubic nanocrystal seeds, facilitating the purification and separation of the CdSe cubic nanocrystal seeds in the mixed solution.

Synthesis of CdSe cubic nanocrystals with a typical size larger than 10 mm: 0.3 mmol of cadmium acetate dihydrate, 0.7 mmol of erucic acid, 0.7 mmol of decanoic acid, and 10 mL of ODE solution were placed into a 25 mL three-necked flask; the flask was purged with argon gas and heated to 150° C., and the temperature was maintained for 10 min, and then further increased to 270° C., and 0.5 mL of 0.1 M octadecanoyl chloride stock solution was added. After 5 min of reaction, purified CdSe cubic nanocrystals prepared previously were added to the mixture. 0.03 M Se-ODE precursor solution was added dropwise to the mixture at a rate of 1.8 mL/h until the CdSe cubic nanocrystals reached the desired size (10 nm). The heating and the dropwise addition of the Se precursor were stopped to stop the reaction. Half of the purified and separated 10 mm CdSe cubic nanocrystals were used for subsequent growth. After dropwise addition of the Se precursor for 4 hours, the size of CdSe cubic nanocrystals reached around 18 nm (PL emission peak position ˜726 nm). If a quarter of the 10 nm CdSe cubic nanocrystals were used for growth for 4 hours, the size thereof would reach 22 nm (PL emission peak position ˜732 mm). The progress of the reaction was quantitatively monitored during the reaction process, where 250 μL of the reaction solution was taken and added to a cuvette containing 2 mL of toluene for UV-Visible absorption and PL emission spectral measurements. Note: When the size of cubic nanocrystals (CdSe, CdS, and CdSe CdS) exceeded 25 nm, a certain amount of octacosanoic acid needed to be added to the reaction system to maintain the solution stability of cubic nanocrystals.

(4) Synthesis of CdS Cubic Nanocrystals

The synthesis of CdS cubic nanocrystals is analogous to the synthesis of CdSe cubic nanocrystals, with the exception that fatty acids need to be added dropwise subsequently; the remaining synthesis steps are similar.

Synthesis of CdS cubic nanocrystals with a typical size smaller than 10 nm: 0.2 mmol of cadmium acetate dihydrate, 1.2 mmol of oleic acid, and 10 mL of ODE solution were placed into a 25 mL three-necked flask; the flask was purged with argon gas and heated to 150° C., and the temperature was maintained for 10 min, and then further increased to 270° C., and 0.4 mL of 0.1 M octadecanoyl chloride stock solution was added. After 5 min of reaction, purified CdS nanocrystal seeds (70 nmol) were added to the mixture. 0.03 MS-ODE precursor solution was added dropwise to the mixture at a rate of 0.6 mL/h until the CdS cubic nanocrystals reached the desired size. When the dropwise added 0.03 M S-ODE solution was prepared by mixing 1 mL of 0.1 M S-ODE with 1 mL of oleic acid and 1 mL of ODE solution, after approximately 3 hours of dropwise addition of S-ODE, the PL emission spectrum peak of the CdS cubic nanocrystals reached 508 nm, with a size of about 8 nm. The progress of the reaction was quantitatively monitored during the reaction process, where 250 μL of the reaction solution was taken and added to a cuvette containing 2 mL of toluene for UV-Visible absorption and PL emission spectral measurements. Similar to the synthesis of CdSe cubic nanocrystals, when the size of CdS cubic nanocrystals exceeded 8 nm, a certain amount of decanoic acid needed to be introduced into the reaction system. The ratio of oleic acid to decanoic acid was as above. At the end of the reaction, 1 mmol of oleic acid was also added to facilitate the purification of CdS cubic nanocrystals.

Synthesis of CdS cubic nanocrystals with a typical size larger than 10 nm: 0.4 mmol of cadmium acetate dihydrate, 1 mmol of erucic acid, 1 mmol of decanoic acid, and 10 mL of ODE solution were placed into a 25 mL three-necked flask; the flask was purged with argon gas and heated to 150° C., and the temperature was maintained for 10 min, and then further increased to 270 ºC, and 0.6 mL of 0.1 M octadecanoyl chloride stock solution was added. After 5 min of reaction, all the purified CdS cubic nanocrystals prepared previously were added to the mixture. 0.03 M S-ODE precursor solution was added dropwise to the mixture at a rate of 1.2 mL/h until the CdS cubic nanocrystals reached the desired size. The heating and the dropwise addition of the S precursor were stopped to stop the reaction. 0.03 M S-ODE solution contained a certain amount of fatty acid, and the optimal molar ratio of fatty acid (erucic acid:decanoic acid=1:1) to sulfur was between 3:1 and 6:1. After 4 hours of growth, the 10 nm CdS cubic nanocrystals (PL emission peak position at 512 am) would reach a size of 20 nm (PL emission peak position at 520 mm). The progress of the reaction was quantitatively monitored during the reaction process, where 250 μL of the reaction solution was taken and added to a cuvette containing 2 mL of toluene for UV-Visible absorption and PL emission spectral measurements.

(5) Synthesis of CdSe CdS Core-Shell Structure Cubic Nanocrystals

CdSex/yCdS core-shell structure cubic nanocrystals were prepared by using x nm (where 3≤x≤16) CdSe cubic nanocrystals as seeds and epitaxially growing y layers of CdS shells. The synthesis conditions for CdSex/yCdS core-shell structure cubic nanocrystals were similar to those for CdS cubic nanocrystals and both required a high concentration of fatty acids to control the growth of the CdS. It was worth noting that the ligand systems for the initial growth of CdSe cubic nanocrystal seeds of different sizes were different. Here, the synthesis of CdSe5/CdS and CdSe8/CdS core-shell cubic nanocrystals would be illustrated as examples.

The typical method for preparing CdSe5/CdS core-shell cubic nanocrystals was as follows: 0.3 mmol of cadmium acetate dihydrate, 0.6 mmol of oleic acid, 0.6 mmol of decanoic acid, and 10 mL of ODE solution were placed into a 25 mL three-necked flask; the flask was purged with argon gas and heated to 150° C., and the temperature was maintained for 10 min, and then further increased to 270° C. and 0.4 mL of 0.1 M octadecanoyl chloride stock solution was added. After 5 min of reaction, purified 5 nm CdSe cubic nanocrystal seeds (half of the quantity of 5 nm CdSe cubic nanocrystals prepared using the typical method for preparing CdSe cubic nanocrystals) were added to the mixture. 0.03 M S-ODE precursor solution was added dropwise to the mixture at a rate of 1.0 mL/h until the CdS shell developed the desired number of layers. The heating and the dropwise addition of the S precursor were stopped to stop the reaction. 0.03 M S-ODE solution contained a certain amount of erucic acid, and the optimal molar ratio of erucic acid to sulfur was between 3:1 and 6:1. After 3 hours of growth, the 5 nm CdSe cubic nanocrystals (PL emission peak position at 660 mm) developed 20 layers of epitaxial CdS shell (cubic nanocrystal size approached 16 nm. PL emission peak position reached 685 mm). The progress of the reaction was quantitatively monitored during the reaction process, where 250 μL of the reaction solution was taken and added to a cuvette containing 2 mL of toluene for measurements such as UV-Visible absorption spectra, steady-state PL emission spectra, and transient photoluminescence spectra.

The typical method for preparing CdSe8/CdS core-shell cubic nanocrystals was as follows: 0.4 mmol of cadmium acetate dihydrate, 1 mmol of erucic acid, 1 mmol of decanoic acid, and 10 mL of ODE solution were placed into a 25 mL three-necked flask; the flask was purged with argon gas and heated to 150° C., and the temperature was maintained for 10 min, and then further increased to 270° C. and 0.6 mL of 0.1 M octadecanoyl chloride stock solution was added. After 5 min of reaction, the purified 8 mm CdSe cubic nanocrystal seeds (half of the quantity of 8 nm CdSe cubic nanocrystals prepared using the typical method for preparing CdSe cubic nanocrystals) were added to the mixture. 0.05 M S-ODE precursor solution was added dropwise to the mixture at a rate of 1.5 mL/h until the CdS shell developed the desired number of layers. The heating and the dropwise addition of the S precursor were stopped to stop the reaction. 0.05 M S-ODE solution contained a certain amount of fatty acid, and the optimal molar ratio of fatty acid (erucic acid:decanoic acid=1:1) to sulfur was between 3:1 and 6:1. After 4 hours of growth, the 8 nm CdSe cubic nanocrystals (PL emission peak position at 695 nm) developed 20 layers of epitaxial CdS shell (cubic nanocrystal size approached 20 nm, PL emission peak position reached 705 nm). The progress of the reaction was quantitatively monitored during the reaction process, where 250 μL of the reaction solution was taken and added to a cuvette containing 2 mL of toluene for measurements of UV-Visible absorption spectra, steady-state PL emission spectra, and transient photolumines cence spectra, etc.

(6) Method for Purifying and Quantifying CdSe and CdS Nanocrystal Seeds

Toluene methanol thermal centrifugation purification scheme: After the reaction, the solution containing CdSe (CdS) nanocrystal seeds was placed into a glass vial, and an ethanol solution twice the volume was added. After shaken up, the mixture was centrifuged at 4000 rpm for 5 min, and the upper ODE solution was discarded. 2 mL of toluene was added into the glass vial and was heated or shaken to dissolve the precipitate (nanocrystal seeds). An equal volume of methanol solution was added and placed on a 100° C. heating stage. After heating for 5 min, the supernatant was discarded after rapid centrifugation at 4000 rpm for 30 seconds.

The toluene dissolution and methanol thermal precipitation process was repeated two times to ensure the complete removal of residual cadmium salts for purification. After vacuum drying the resulting precipitate (nanocrystal seeds) for 20 min, 2 mL of ODE solution was added and heated to dissolve the precipitate. The concentration of the purified nanocrystal seed ODE solution was quantitatively calibrated for later use. The specific quantification method was as follows: A certain amount of the purified nanocrystal seed ODE solution was weighed and added to a known amount of toluene solution. After shaking up, the mixture was subjected to UV-Visible absorption spectral measurement. Using the extinction coefficient of nanocrystals reported in the literature, the concentration of nanocrystal seeds in the solution could be calculated. It was worth noting that the reported extinction coefficient here was applicable only to spherical nanocrystals and non-cubic nanocrystals, as it involved spherical approximation and non-cubic approximation during nanocrystal size calculations.

(7) Method for Purifying, Separating, and Quantifying CdSe, CdS, and CdSe CdS Cubic Nanocrystals

The synthesis strategy of CdSe or CdS cubic nanocrystals with typical sizes smaller than 10 nm often resulted in a mixture of both the desired product (cubic nanocrystals) and a small amount of byproducts (non-cubic nanocrystals). The primary task was to separate these byproducts to obtain the desired product. Since the size of the byproducts in the synthesized product was much smaller than that of the desired product, the solubility of the byproducts in the reaction system was higher than that of the desired product. Therefore, the difference in solubility was utilized to separate and remove the byproducts. The specific purification method was as follows: The reaction solution was placed in a glass vial and kept on a 100° C. heating stage for 5 min. After shaking up, the solution was centrifuged at 4000 rpm for 5 min, and then the supernatant was discarded to remove most of the byproducts and the reaction solvent (ODE). 4 mL of toluene was added and shaken or heated to dissolve the precipitate, and then 0.4 mL of acetonitrile precipitant was added. After shaken up, the mixture was centrifugated at 4000 rpm for 1 min, and the supernatant was discarded. The precipitate was the desired product, i.e., CdSe (CdS) cubic nanocrystals, but it still contained unreacted cadmium salt precursor, etc. The purification process with two times of toluene methanol thermal centrifugation could effectively remove unreacted cadmium salt precursors and other impurities, achieving the purpose of purification. Finally, the separated and purified CdSe (CdS) cubic nanocrystals were dissolved in 2 mL of hexane for further use.

Using purified CdSe (CdS) cubic nanocrystals as seeds enabled subsequent growth of morphology-monodispersed CdSe, CdS, and CdSe CdS cubic nanocrystals. The toluene methanol thermal centrifugation purification scheme could also effectively purify the desired products. However, this method would significantly affect the optical properties of the cubic nanocrystals. Therefore, for cubic nanocrystals intended for optical property studies, a milder precipitant such as isopropanol was used for the purification process. The specific purification method was as follows: The reaction solution was placed in a glass vial and added with 1.5-2 times the volume of isopropanol solution. The mixture was placed on a 100° C. heating stage for 5 min, and then centrifuged at 4000 rpm for 1 min, and the supernatant was discarded. 0.5 mL of hexane was added and shaken or heated to dissolve the precipitate. Afterward, 3 mL of ODE solution was added and shaken up, and then 1.5-2 times the volume of Isopropanol solution was added. The mixture was placed on a 100° C. heating stage for 5 min, and finally centrifuged at 4000 rpm for 1 min, and the supernatant was discarded. 2 mL of toluene was added to dissolve the precipitate for further use.

[Sample Characterization]

(1) UV-Visible Absorption Spectrum

Prior to sample testing, a baseline was collected from a blank good solvent (toluene, hexane, chloroform, etc.) and saved for the testing method. For the sample testing, a certain amount of nanocrystal solution was taken and added to a quartz cuvette containing a certain amount (22 mL) of good solvent. The corresponding testing method for the solvent was opened, zeroing was performed, and then UV-Visible absorption spectral measurement was performed. The UV-Visible absorption spectra obtained through this process had the solvent background subtracted and the absorbance was zeroed at the maximum wavelength. The quartz cuvette had an optical distance of 1 cm. The common testing range for UV-Visible absorption spectra was 300-800 nm, and the spectral acquisition step was 0.5-1 nm.

(2) Steady-State Photoluminescence Spectrum

A certain amount of nanocrystal solution was taken and added to a quartz cuvette containing a certain amount (≥2 mL) of good solvent (toluene, hexane, chloroform, etc.) for steady-state photoluminescence spectral testing (PL emission and excitation spectra). During photoluminescence spectral testing, the sample concentration should not be too high, typically with an absorbance of not exceeding 0.1, to avoid severe reabsorption effects. During PL emission spectral testing, the common excitation wavelength for CdSe (CdSe/CdS) nanocrystals was 400 nm, and the common excitation wavelength for CdS nanocrystals was 350 nm. However, during photoluminescence up-conversion testing, the excitation wavelength was greater than the corresponding nanocrystal PL emission peak position. The spectral acquisition step (0.2-1 nm) was determined as appropriate, with a smaller step being used for calculating photoluminescence FWHM.

(3) Transient Photoluminescence Spectrum

A certain amount of nanocrystal solution was taken and added to a quartz cuvette containing a certain amount (>2 mL) of toluene solution for transient photoluminescence spectral testing. Due to significant differences in exciton decay dynamics in different medium environments, unless specified otherwise, the solvent used for transient photoluminescence testing was toluene solution. The instrument used for transient photoluminescence spectrum was the Edinburgh Instrument photoluminescence spectrometer (FLS920, Edinburgh Instrument, UK), the excitation light source was a picosecond laser with a wavelength of 405 nm and operating at a repeated frequency of 2 MHZ. During transient photoluminescence testing, the photon count was set between 1000 and 5000 for each acquisition. If the mono-exponential goodness of fit χ² of the photoluminescence decay curve was less than or equal to 1.3, the photoluminescence of the corresponding nanocrystal was a mono-exponential decay. The PL lifetime τ was obtained by fitting the decay curve using a single exponential function.

(4) Infrared Absorption Spectrum

The infrared spectrum testing herein mainly focused on carbonyl compounds (RCOO—, RCOOH, R1COOCOR₂), with the solvents commonly used for the testing being dodecane or ODE solutions. The cuvette for the testing was a homemade small optical distance cuvette, constructed as follows: Two calcium fluoride windows (15 mm×15 mm×1 mm) served as the windows, and two alumina ceramics (15 mm×2 mm×0.5 mm) served as spacers. The two symmetric spacers were clamped together using binder clips with surface paint removed. Utilizing liquid surface tension, the cuvette could hold about 100 μL of the test solution. During testing, the solvent was first tested as a blank, then a 200 μL pipette was used to carefully add the test solution to the cuvette for infrared testing. The obtained infrared spectra had the solvent background further subtracted.

(5) Transmission Electron Microscope

Low-resolution transmission electron microscope (TEM) testing: The nanocrystal solution (whether purified or not) was taken and diluted with a certain amount of toluene solution and then gradually dropped onto an ultrathin carbon film. TEM testing was performed once the solvent had completely volatilized.

High-resolution transmission electron microscope (HRTEM) testing: The purified nanocrystal solution was dissolved in a certain amount of toluene solution and then gradually dropped onto an ultrathin carbon film. HRTEM testing was performed once the solvent had completely volatilized.

(6) Scanning Electron Microscope

The purified and vacuum-dried nanocrystal powder was coated on a conductive adhesive, and then the conductive adhesive was affixed to a silicon wafer for scanning electron microscope testing. The main purpose of scanning electron microscope testing herein was elemental quantitative analysis and characterization of the self-assembly of cubic nanocrystals.

(7) X-Ray Powder Diffraction

The purified and vacuum-dried nanocrystal powder was spread evenly onto a silicon wafer and then placed in a quartz glass sample well for X-ray powder diffraction testing. Testing conditions: 40 KV/30 mA, Cu target (λ=1.5418 Å).

(8) Small-Angle X-Ray Scattering

The purified and vacuum-dried nanocrystal powder was adhered to a KAPTOM film for small-angle X-ray scattering (SAXS) testing. Testing conditions: 50 KV/0.6 mA, Cu target (λ=1.5418 Å).

(9) Single Particle Spectral Testing

The nanocrystal solution was diluted (typically diluted by a factor of 100,000) with dehydrated toluene solution using a sodium plate and then mixed with a polymethyl methacrylate (PMMA) toluene solution (0.5-1.5 wt %). The diluted nanocrystal solution was dropped onto a cleaned glass slide using a pipette and then spin-coated into a film using an adhesive dispenser. Testings for single-particle photoluminescence spectrum. PL intensity, PL lifetime, etc were performed using an inverted photoluminescence microscopy system independently constructed in the group.

(10) Spherical Aberration Correction Field Emission Scanning Transmission Electron Microscope

The purified nanocrystal solution was dissolved in a certain amount of toluene solution and then gradually dropped onto an ultrathin carbon film. HAADF-STEM testing was performed once the solvent had completely volatilized. The STEM testing herein was mainly aimed at cubic nanocrystal atom characterization and CdSe/CdS core-shell cubic nanocrystal element mapping analysis.

[FIG. 1]

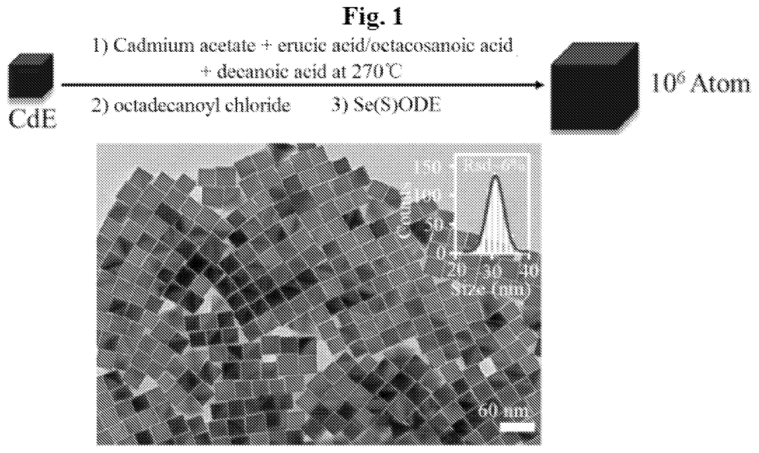

The basic synthetic route for large-sized CdE cubic nanocrystals is shown in FIG. 1 (top). In this synthesis route, small-sized (≤ 10 nm) CdE cubic nanocrystals serve as seeds, wherein the CdE cubic nanocrystals include CdSe, CdS, and CdSe CdS cubic nanocrystals. Cadmium acetate, erucic acid (octacosanoic acid), decanoic acid, and octadecanoyl chloride reaction products (cadmium carboxylate chloride) serve as cationic precursors and organic ligands on the surface of the cubic nanocrystals. Se-ODE (S-ODE) serves as the anionic precursor, and ODE serves as the solvent. The resulting CdE cubic nanocrystals can achieve a size of up to 30 mm while maintaining size and morphology monodispersity. As depicted in FIG. 1, in the synthetic system of large-sized CdE cubic nanocrystals, CdSe cubic nanocrystals are used as seeds for growth, and by employing a ligand system composed of octacosanoic acid salts, erucic acid salts, and decanoic acid salts, CdSe cubic nanocrystals with a size of up to 30 mm (bottom) and monodisperse size and morphology can be obtained. The nanocrystal size shown in FIG. 1 is significantly larger than the maximum size of monodisperse CdSe nanocrystals reported in the literature. This well indicates the feasibility of the synthetic system for large-sized CdE cubic nanocrystals in achieving large-sized and monodisperse nanocrystal synthesis. It also confirms the feasibility of preparing monodisperse large-sized CdE cubic nanocrystals under this ligand system.

[FIG. 2]

FIG. 2 shows the characterization results of 21 nm CdSe cubic nanocrystals, and the CdSe cubic nanocrystals are prepared using the method according to the embodiments.

In FIG. 2a, the TEM image shows well-defined square two-dimensional projections with a relative standard deviation of the size distribution of only 3% (top left graph in FIG. 2a), indicating that the CdSe nanocrystals possess good size and morphology monodispersity.

High-resolution electron microscope characterization results in FIGS. 2(b, c, d) show that the clear lattice fringes of single-period and dislocation-free indicate a good single-crystalline nature of the CdSe cubic nanocrystals; the atomically smooth boundaries indicate the smoothness of the nanocrystal faces, namely the integrity of the cubic morphology; the lattice spacing consistent with the zinc-blende lattice parameter indicates the zinc-blende structure of the CdSe cubic nanocrystals.

The XRD characterization results in FIG. 2(e), which strictly correspond to the diffraction peaks on the standard card, further demonstrate that the CdSe cubic nanocrystals have a zinc-blende structure without obvious defects, and the extremely narrow diffraction peaks reflect the larger size of the nanocrystals.

The above characterization results indicate that the prepared CdSe cubic nanocrystals are monodisperse in size and morphology, and have a zinc-blende single-crystal structure with excellent crystallinity.

In FIG. 2(f), the normalized PLE spectra at different emission positions of 21 nm CdSe cubic nanocrystals completely overlap, indicating their good size monodispersity, and that their size distribution does not affect the exciton energy level structure of the nanocrystals. Photoluminescence excitation spectra reflect how the PL emission intensity varies with excitation energy (excitation wavelength) at a fixed PL emission position. Generally, only when nanocrystal size is monodisperse, the corresponding excitonic states of the nanocrystals can be monodisperse. Under this condition, the photoluminescence contributions from different emission peaks in the photoluminescence spectra originate from the same nanoparticle. Therefore, the PLE spectra at different emission positions of the nanocrystals are identical.

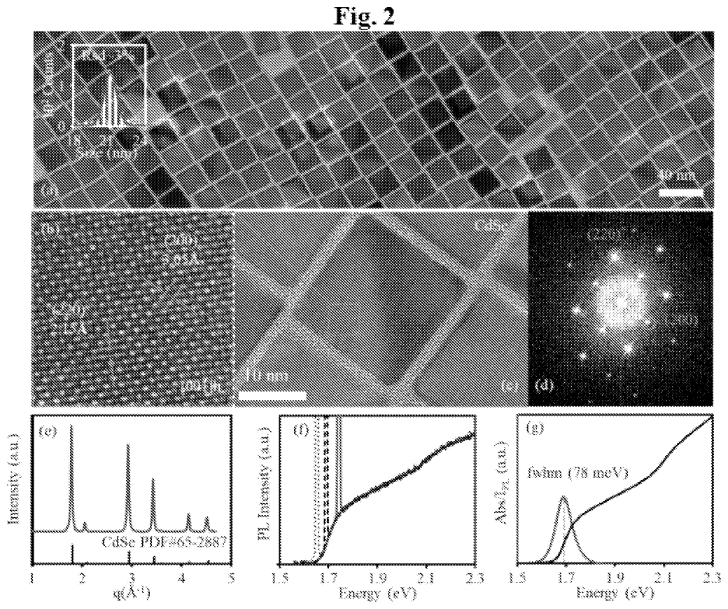

FIG. 2(g) shows the absorption and PL emission spectra of the 21 nm CdSe cubic nanocrystals. The absorption spectrum lacks distinct exciton absorption peaks and exhibits a bulk-like quasi-continuous band absorption, and the corresponding PL emission peak position is at 1.69 eV, very close to the zinc-blende CdSe bulk bandgap of 1.66 eV (300 K). These bulk-like properties indicate that the 21 nm CdSe cubic nanocrystals have only weak quantum confinement effects, classifying them as weakly-confined nanocrystals. Furthermore, it is worth noting that the corresponding photoluminescence spectrum FWHM of the nanocrystals is not narrower than that of small-sized strongly-confined quantum dots as predicted in the literature. Instead, the corresponding photoluminescence spectrum FWHM widens to 78 meV and the photolumines cence spectrum shows a slightly asymmetric tailing towards higher energy.

[FIG. 3]

FIG. 3 shows the characterization results of 21 min CdS cubic nanocrystals, and the CdS cubic nanocrystals are prepared using the method according to the embodiments.

In FIG. 3(a), the TEM image shows uniformly regular square two-dimensional projections with a relative standard deviation of the size distribution of only 5% (top left graph in FIG. 3a), indicating that the CdS cubic nanocrystals possess good size and morphology monodispersity.

High-resolution electron microscope characterization results in FIGS. 3(b, c, d) show that the CdS nanocrystals are of a zinc-blende crystal form, and possess good single-crystalline nature and regular cubic morphology.

The XRD characterization results in FIG. 3(e), which strictly correspond to the diffraction peaks on the standard card, further indicate the zinc-blende structure of the CdS cubic nanocrystals, and the extremely narrow diffraction peaks align with the relatively large size of the CdS nanocrystals.

The above characterization results indicate that the prepared CdS cubic nanocrystals are monodisperse in size and morphology, and have a zinc-blende single-crystal structure with excellent crystallinity.

In FIG. 3(f), the completely overlapping PLE spectra from different PL emission positions indicate good size and morphology monodispersity of the CdS cubic nanocrystals, and their size distribution does not affect the exciton energy level structure of the nanocrystals.

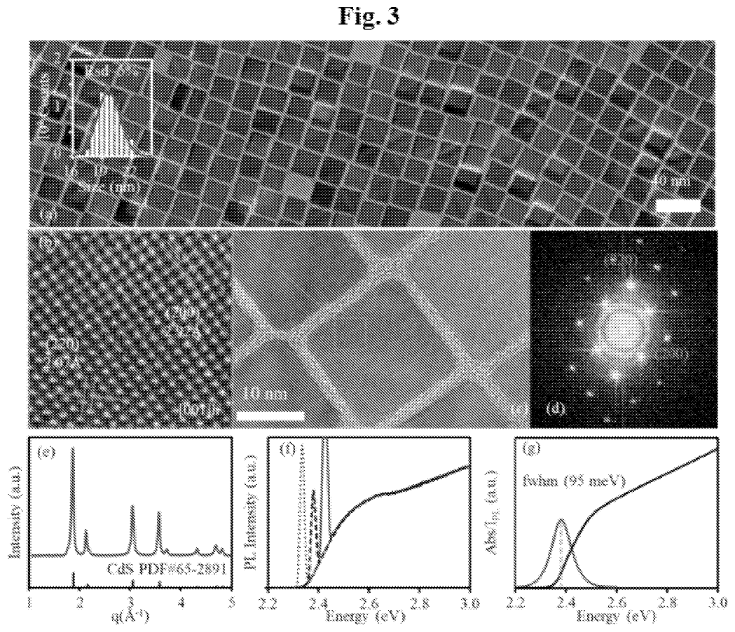

FIG. 3(g) is the corresponding absorption and PL emission spectra. Compared to CdSe cubic nanocrystals, the normalized absorption spectrum of the CdS cubic nanocrystals exhibits a more bulk-like quasi-continuous band absorption, and their corresponding PL emission peak position is at 2.38 eV, which is consistent with the bandgap of 2.38 eV (300 K) for bulk zinc-blende CdS reported in the literature. This is because the exciton Bohr radius of CdS is only about 2.6 nm. The 21 nm CdS cubic nanocrystals fall into the category of extremely weakly-confined nanocrystals, resulting in spectral properties highly resembling those of the bulk CdS. Similar to weakly-confined CdSe cubic nanocrystals, CdS cubic nanocrystals also have a broad photoluminescence FWHM of up to 95 meV, but their corresponding photoluminescence spectra do not display significant asymmetry. This is because within the size range, the energies of the two lowest emission energy levels of CdS are very close, resulting in roughly equal double-peak emission intensities, widening the photolumines cence spectrum without exhibiting distinct asymmetry.

[FIG. 4]

FIG. 4 shows the characterization results of 20 nm CdSe8/CdS cubic nanocrystals prepared by using 8 nm CdSe cubic nanocrystals as nanocrystal seeds and subsequently adding S-ODE precursor thereto, and the CdSe8/CdS cubic nanocrystals are prepared using the method according to the embodiments.

In FIG. 4(a), the TEM image shows uniformly regular square two-dimensional projections with a standard deviation of the size distribution of only 4%, indicating the well-maintained monodispersity in size and morphology of CdSe8/CdS cubic nanocrystals.

High-resolution electron microscope characterization results in FIGS. 4(c, d, e) show clear lattice fringes of single-period and dislocation-free with atomically smooth boundaries, indicating that CdSe8/CdS nanocrystals possess good single-crystalline nature and regular cubic morphology. The element distribution map in FIG. 4(b) indicates that the nanocrystals possess a CdSe CdS core-shell structure with CdS completely encapsulating CdSe, and their interplanar spacing of specific crystal faces is between the interplanar spacings of corresponding crystal faces in zinc-blende CdSe and CdS, indicating that the nanocrystals are of a zinc-blende crystal form.

XRD characterization results in FIG. 4(f) show that the diffraction peaks are between those of standard cards for zinc-blende CdSe and CdS, further demonstrating the good zinc-blende structure of CdSe8/CdS core-shell nanocrystals.

The above structure characterization results indicate that the prepared CdSe8/CdS cubic nanocrystals are monodisperse in size and morphology and have a zinc-blende single-crystal structure with excellent crystallinity.

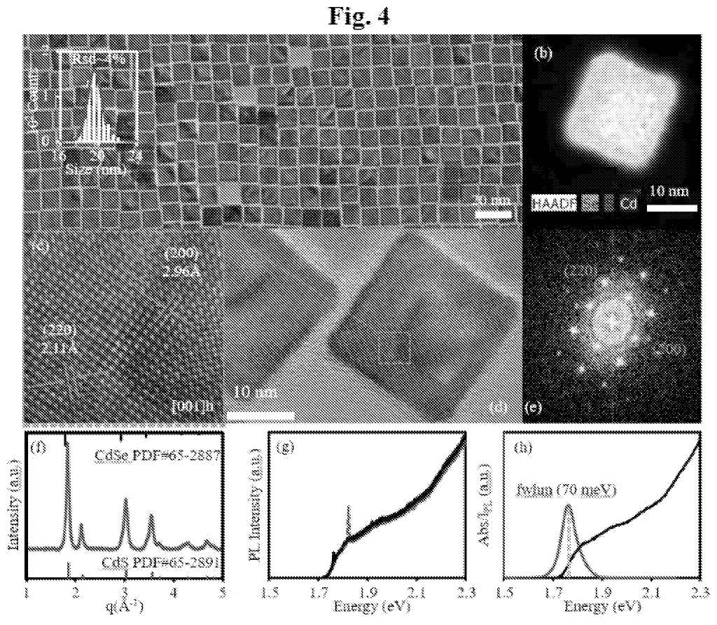

The completely overlapping PLE spectra from different PL emission positions (FIG. 4g) also indicate the monodispersity in size and morphology as well as the monodisperse exciton states of the nanocrystals. Similar to weakly-confined CdSe and CdS, their normalized absorption spectra also exhibit bulk-like quasi-continuous band absorption (FIG. 4h), indicating that the 20 nm CdSe8/CdS cubic nanocrystals also fall into the category of weakly-confined nanocrystals. Due to the contribution of the epitaxial CdS shell, CdSe8/CdS exhibits significantly enhanced absorbance at short wavelengths compared to CdSe nanocrystals. Additionally, the epitaxial growth of CdS onto CdSe forms a quasi-type II core-shell structure, where the epitaxial CdS shell shows a certain confinement effect on the hole. Hence, compared to same-sized CdSe cubic nanocrystals. CdSe8/CdS cubic nanocrystals have higher band-edge absorption and emission peak energies. It is worth noting that the photoluminescence spectrum of the weakly-confined CdSe8/CdS cubic nanocrystals at the size also has a relatively wide FWHM (70 meV), and the photoluminescence spectrum exhibits a distinct asymmetric feature with a tailing towards higher energy.

[FIG. 5]

FIG. 5 shows the characterization results of 22 nm CdSe12/CdS cubic nanocrystals growing by using 12 nm CdSe cubic nanocrystals as seeds and subsequently adding S-ODE precursor thereto, and the CdSe12/CdS cubic nanocrystals are prepared using the method according to the embodiments.

Similar to the large-sized CdSe, CdS, and CdSe8/CdS cubic nanocrystals, the TEM image in FIG. 5a shows uniformly regular square two-dimensional projections with a standard deviation of the size distribution of only 3%, indicating that the 22 nm CdSe12/CdS cubic nanocrystals are also monodisperse in size and morphology.

High-resolution electron microscope characterization results in FIGS. 5(c, d, e) show clear lattice fringes of single-period and dislocation-free with atomically smooth boundaries, indicating that CdSe12/CdS nanocrystals possess good single-crystalline nature and regular cubic morphology. The element distribution map in FIG. 5(b) indicates that the nanocrystals possess a CdSe CdS core-shell structure with CdS completely encapsulating CdSe, and their interplanar spacing (FIG. 5c) of specific crystal faces is between the interplanar spacings of corresponding crystal faces in zinc-blende CdSe and CdS, indicating that the nanocrystals are of a zinc-blende crystal form.

XRD characterization results of FIG. 5(f) show that the diffraction peaks are between those of standard cards for zinc-blende CdSe and CdS, indicating the good zinc-blende structure of CdSe12/CdS core-shell nanocrystals.

The above characterization results indicate that the prepared CdSe12/CdS cubic nanocrystals are monodisperse in size and morphology and have a zinc-blende single-crystal structure with excellent crystallinity.

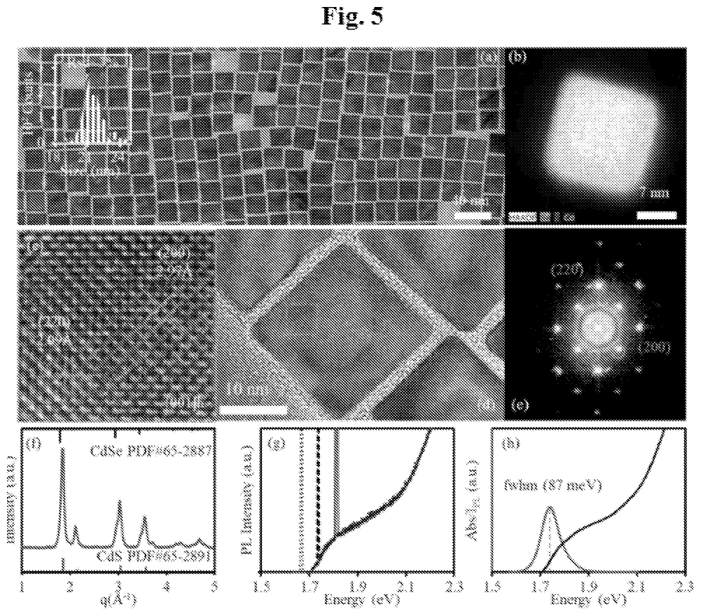

The completely overlapping PLE spectra from different PL emission positions (FIG. 5d) indicate the monodispersity in size and morphology as well as the monodisperse exciton states of the nanocrystals. Similar to weakly-confined CdSe, CdS, and CdSe8/CdS cubic nanocrystals, their normalized absorption spectra also exhibit bulk-like quasi-continuous band absorption, indicating that the 22 nm CdSe12/CdS cubic nanocrystals also fall into the category of weakly-confined nanocrystals, and due to the contribution of the epitaxial CdS shell, CdSe12/CdS exhibits significantly enhanced absorbance at short wavelengths compared to CdSe nanocrystals. Additionally, similar to CdSe8/CdS cubic nanocrystals, CdSe12/CdS cubic nanocrystals have higher band-edge absorption and emission peak energies compared to same-sized CdSe cubic nanocrystals. It is worth noting that the photoluminescence spectrum of the weakly-confined CdSe12/CdS cubic nanocrystals at the size also exhibits a relatively wide FWHM (87 meV), and the photoluminescence spectrum also exhibits a distinct asymmetric feature with a tailing towards higher energy.

[FIG. 6]

FIG. 6(a) shows the normalized UV-Visible absorption spectra/PL emission spectra of different-sized CdSe cubic nanocrystals. As the nanocrystal size increases, the center peaks of the photoluminescence spectra and the band edges of the absorption spectra gradually shift towards lower energy, and the exciton absorption peaks in the absorption spectra transition into a shoulder peak and eventually become a bulk-like quasi-continuous band absorption feature. In the figure, when the size of the nanocrystals increases from 11 nm to 13 nm, the shoulder peak of the first exciton absorption peak in the corresponding absorption spectrum disappears. This also indicates that as the size increases, the quantum confinement effect of CdSe nanocrystals gradually diminishes into the size range of weak confinement.

As shown in FIG. 6(b), the size of CdSe cubic nanocrystals Increases from 5 nm to 21 nm, resulting in the corresponding photoluminescence peak shifting from 1.88 eV to 1.69 eV. However, it is worth noting that the rate of photoluminescence peak shift varies across size ranges. In the size range of 5 nm to 12 nm, the photoluminescence peak of CdSe cubic nanocrystals shows a monotonous redshift. In the size range of approximately 12 nm to 17 nm, the photoluminescence remains relatively stable. Beyond the range of about 17 min, the photoluminescence peak shows a redshift again. According to Brus equation, the bandgap of semiconductor nanocrystals is closely related to the kinetic energy term (∝D⁻², where D represents the nanocrystal size) arising from the size-dependent quantum confinement effect. As the nanocrystal size Increases, the kinetic energy arising from the quantum confinement effect gradually decreases and approaches zero. Consequently, the nanocrystal bandgap gradually decreases, and the rate of decrease becomes progressively slower.

The photoluminescence spectrum FWHM of nanocrystals is a common indicator for evaluating the quality of the nanocrystals. FIG. 6(c) shows the variation of the photoluminescence FWHM of CdSe cubic nanocrystals with size. When the size of CdSe cubic nanocrystals increases from 5 nm to 21 nm, the corresponding photoluminescence FWHM initially gradually decreases to around 50 meV, then rapidly increases to around 90 meV, followed by a gradual decrease and fluctuation around 75 meV. Given the good size and morphology monodispersity of the CdSe cubic nanocrystals prepared, the changing trend in the aggregate photoluminescence spectrum FWHM of the CdSe cubic nanocrystals here can also reflect the change trend in their intrinsic photoluminescence FWHM.

Part of the photoluminescence spectra in FIG. 6(a) shows a distinct asymmetric feature with a tailing towards higher energy, wherein the photoluminescence spectrum of the 12 nm CdSe cubic nanocrystals shows the most distinct asymmetry (the inset in FIG. 6b).

FIG. 6(c) shows the calculation results of the photoluminescence spectra skewness for different-sized CdSe cubic nanocrystals. As the size increases, the photoluminescence spectra skewness of the CdSe cubic nanocrystals sharply increases and then slightly decreases. The size range of the sharp increase in photoluminescence peak skewness of the nanocrystals highly corresponds to the range of the rapid photoluminescence FWHM increase of the nanocrystals. This indicates that the widening of the photoluminescence spectra FWHM of the CdSe cubic nanocrystals is caused by the appearance of an asymmetric tailing in their photoluminescence spectra.

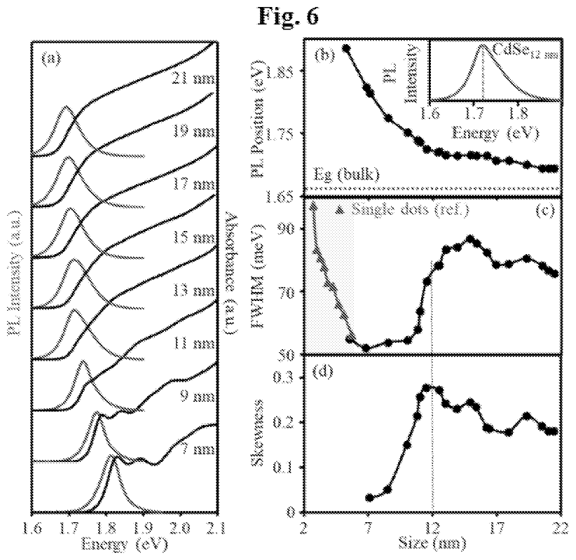

The exciton Bohr radius of CdSe is about 5.6 mm. However, the disappearance of the first exciton absorption peak, the rapid increase in photoluminescence FWHM, and the maximum photoluminescence spectrum skewness all correspond to cubic CdSe nanocrystals with a size around 12 mm. i.e., approximately the exciton Bohr diameter. This is not coincidental, as exciton Bohr diameter is generally considered a fundamental criterion to distinguish the strength of confinement effects in semiconductor nanocrystals.

[FIG. 7]

FIG. 7(a) shows the normalized UV-Visible absorption spectra/PL emission spectra of different-sized CdS cubic nanocrystals. Similar to the size-dependent optical properties of CdSe cubic nanocrystals, as the nanocrystal size increases, the center peaks of the photoluminescence spectra and the band edges of the absorption spectra gradually shift towards lower energy, and the exciton absorption peaks in the absorption spectra transition from a shoulder peak to a bulk-like quasi-continuous band absorption feature.

As shown in FIG. 7(b), when the size of CdS cubic nanocrystals increases from 8 mm to 20 nm, the corresponding photoluminescence peak shifts from 2.44 eV to the zinc-blende CdS bulk bandgap of 2.38 eV. This indicates that the 20 nm CdS cubic nanocrystals have exhibited absorptive properties as bulk materials. Additionally, the photoluminescence peak of the CdS cubic nanocrystals also shifts rapidly at first and then becomes relatively stable, which is similar to the phenomenon observed in CdSe. Additionally, when the size of CdS cubic nanocrystals reaches 8 nm, the corresponding band edge of the absorption spectrum exhibits a shoulder peak instead of a distinct exciton absorption peak. This is because CdS has a smaller exciton Bohr radius, and the 8 nm CdS nanocrystals already possess a relatively high density of states at the absorption band edge. When the size of CdS nanocrystals increases from 10 nm to 12 nm, the shoulder peak of the first exciton absorption peak in the corresponding absorption spectrum completely disappears. This also indicates that as the size increases, the quantum confinement effect gradually diminishes, causing the corresponding CdS cubic nanocrystals to enter the category of weakly-confined nanocrystals.

FIG. 7(c) shows the variation of the photoluminescence FWHM of CdS cubic nanocrystals with size. When the size of CdS cubic nanocrystals increases from 8 nm to 20 nm, the corresponding photoluminescence FWHM initially rapidly increases to around 100 meV and then slightly decreases. This is different from the variation trend of photoluminescence FWHM with size observed in CdSe nanocrystals.

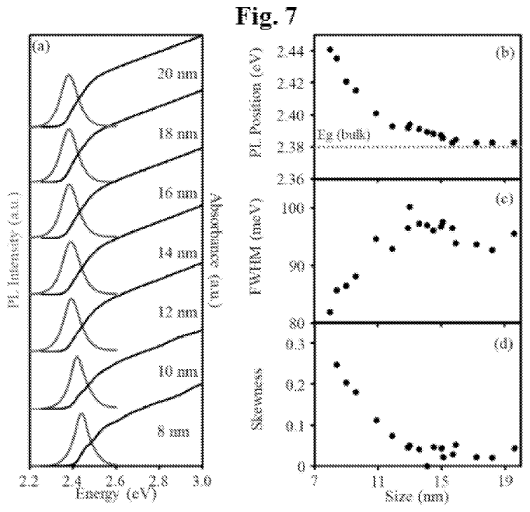

The calculation results of the photoluminescence spectra skewness for different-sized CdSe cubic nanocrystals (FIG. 7d) show that when the size of CdS cubic nanocrystals increases from 8 nm to 20 mm, the photoluminescence spectra skewness of the CdS cubic nanocrystals gradually decreases. This is also different from the variation trend of photoluminescence spectra skewness with size observed in CdSe nanocrystals, indicating that the size-dependent optical properties of CdSe and CaS are different because of their different exciton Bohr radii, and their confinement effect intensities are different within the same size range. The exciton Bohr radius of CdSe nanocrystals is approximately twice that of CdS nanocrystals, implying that the confinement effects in 8 nm CdS nanocrystals are roughly equivalent to those in 16 nm CdSe nanocrystals. From this perspective, the spectral behavior of CdS cubic nanocrystals with sizes above 8 nm should be comparable to that of CdSe cubic nanocrystals with sizes above 16 nm, which is also basically consistent with the experimental results. The skewness calculation results indicate that the photoluminescence spectra of CdS cubic nanocrystals also exhibit asymmetry, and the photoluminescence spectra also tend to be skewed towards higher energy. This is similar to the phenomenon observed in the photoluminescence spectra of CdSe cubic nanocrystals. This Indicates that the trend of photoluminescence spectra becoming asymmetric with increasing nanocrystal size is a common characteristic of both CdSe and CdS nanocrystals.

[FIG. 8]

CdSe8/yCdS (where y represents the number of CdS monolayers) cubic nanocrystals prepared by using 8 nm CdSe cubic nanocrystals as nanocrystal seeds and epitaxial CdS shells in large-sized CdE cubic nanocrystal synthetic route are investigated. FIG. 8(a) shows the normalized absorption spectra of CdSe8/yCdS cubic nanocrystals with different CdS shell thicknesses. As the CdS shell thickness increases, the absorbance at higher energy gradually increases in the corresponding absorption spectra, and the exciton absorption peak features in the corresponding absorption spectra gradually disappear and become bulk-like quasi-continuous band absorption features. This indicates that the density of states at the absorption band edge of CdSe8 yCdS cubic nanocrystals gradually increases, showing weak confinement characteristics.

FIG. 8(b) shows the normalized photoluminescence spectra of CdSe8/yCdS cubic nanocrystals with different CdS shell thicknesses. As the CdS shell thickness increases, the corresponding photoluminescence peak shifts towards lower energy by approximately 20 meV. Specifically (FIG. 8d), after epitaxially growing 5 layers of CdS onto 8 nm CdSe cubic nanocrystals, their photoluminescence peak shifts from 1.78 eV to 1.76 eV. Upon further epitaxial growth of CdS, the overall photoluminescence peak slightly shifts towards higher energy instead. According to Brus equation, as the nanocrystal size increases, the bandgap gradually decreases, which should lead to a shift of the photoluminescence peak towards lower energy. For the CdSe/CdS quasi-type II core-shell nanocrystals, although only electrons can be delocalized within the entire nanocrystal, they should still possess size-dependent quantum confinement effects. From this perspective, even though CaSe8/yCdS nanocrystals fall into the category of weak confinement, the corresponding photoluminescence peak should not shift towards higher energy with increasing CdS shell thickness.

An analysis of the photoluminescence spectra for CdSe8/yCdS cubic nanocrystals with different CdS shell thicknesses is performed. As shown in FIG. 8(e), as the CdS shell thickness increases, the skewness of the corresponding photoluminescence spectra of CdSe8/yCdS gradually increases, and the photoluminescence spectra FWHM also increases. It can be observed from FIG. 8(b) that as the CdS shell thickness increases, the photoluminescence spectra of CdSe8/yCdS cubic nanocrystals gradually rise at higher energy. This indicates that the photoluminescence spectra of CdSe8/yCdS cubic nanocrystals also show asymmetric features. Additionally, it is worth noting that although the photoluminescence spectrum peak shifts towards higher energy with increasing CdS shell thickness in FIG. 8(b), the falling edges of the photoluminescence spectra at lower energies substantially overlap. This indicates that the shifting of the photoluminescence spectrum peak towards higher energy is caused by the gradual tailing of the photolumines cence spectrum towards higher energy, I.e., the anomalous phenomenon is also caused by the asymmetry of the photoluminescence peak.

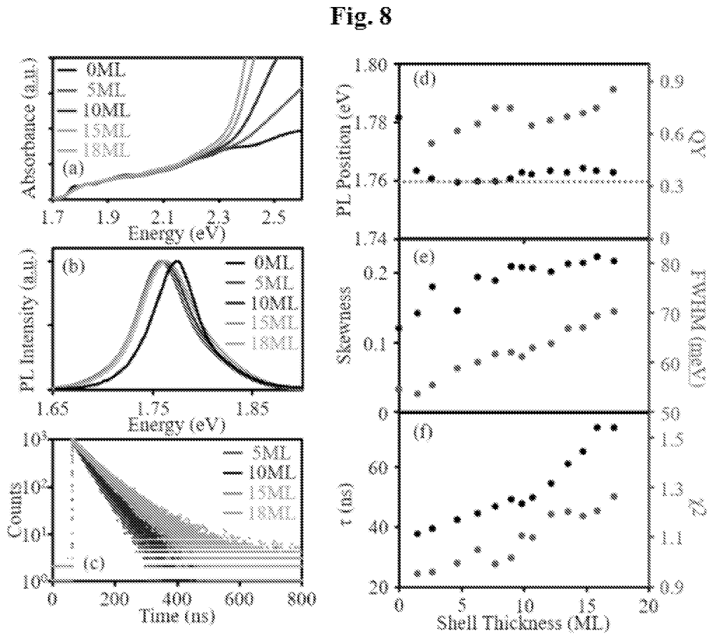

FIG. 8(c) shows transient photoluminescence spectra of CdSe8/yCdS cubic nanocrystals with different CdS shell thicknesses. As the CdS shell thickness increases, the PL lifetime of CdSe8/yCdS gradually increases. Specifically, as shown in FIG. 8(f), after epitaxially growing 2 layers of CdS shells, the PL lifetime of CdSe8/2CdS is around 38 ns, while after epitaxially growing 18 layers of CdS shells, the PL lifetime of CdSe8/18CdS reaches 73 ns. Furthermore, although the goodness of fit χ² of the transient photoluminescence gradually increases with increasing CaS shell thickness, its value remains below 1.3. Therefore, the transient photoluminescence spectra of CdSe8/yCdS cubic nanocrystals conform to the characteristics of single-channel decay. From this perspective, CdSe8/yCdS cubic nanocrystals synthesized under the synthesis strategy of weakly-confined CdE cubic nanocrystals possess good optical properties.

[FIG. 9]

CdSe12/CdS cubic nanocrystals prepared by using 12 nm CdSe cubic nanocrystals as nanocrystal seeds and epitaxially growing CdS shells are investigated. FIG. 9(a) shows the normalized absorption spectra of CdSe12/yCdS cubic nanocrystals with different CdS shell thicknesses. As the CdS shell thickness increases, similar to CdSe8/yCdS cubic nanocrystals, the absorbance at higher energy gradually increases in the corresponding absorption spectra. Moreover, the corresponding absorption spectra consistently exhibit bulk-like quasi-continuous band absorption features. This indicates that CdSe12/yCdS cubic nanocrystals also fall into the category of weakly-confined nanocrystals.

FIG. 9(b) shows the normalized photoluminescence spectra of CdSe12/yCdS cubic nanocrystals with different CdS shell thicknesses. As the CdS shell thickness increases, the corresponding photoluminescence peak continues to shift towards higher energy Specifically (FIG. 94), after epitaxially growing 19 layers of CdS onto 12 nm CdSe cubic nanocrystals, their photoluminescence peak shifts from 1.725 eV to 1.739 eV. This is the same as the shifting trend of a part of photoluminescence positions observed in CdSe8/yCdS cubic nanocrystals, indicating that the photoluminescence peak of CaSex/yCdS cubic nanocrystals shifts instead towards higher energy with increasing CdS shell thickness, and this might not be coincidental but rather a common characteristic of weakly-confined CdSex/yCdS nanocrystals. Additionally, similar to CdSe8/yCdS cubic nanocrystals, although the photoluminescence spectrum peak of CdSe12/yCdS cubic nanocrystals shifts slightly towards higher energy with increasing CdS shell thickness in FIG. 9(b), the falling edges of the photoluminescence spectra at lower energies also substantially overlap. This indicates that the shifting of the photoluminescence spectrum peak towards higher energy is also caused by the gradual tailing of the photoluminescence spectrum towards higher energy.

An analysis of the photoluminescence spectra for CdSe12/yCdS cubic nanocrystals with different CdS shell thicknesses is performed. As shown in FIG. 9(e), as the CdS shell thickness increases, the skewness and the FWHM of the corresponding photoluminescence spectra of CdSe12/yCdS cubic nanocrystals also gradually increase. It can be observed more clearly from FIG. 9(b) that as the CdS shell thickness increases, the tailing towards higher energy in the photolumines cence spectra of CdSe12/yCdS becomes more pronounced. This indicates that the photoluminescence spectra of CdSe12/yCdS cubic nanocrystals also show distinct asymmetric features.

The aggregate photoluminescence spectra and the single-particle photoluminescence spectra of CdSe12/20CdS cubic nanocrystals completely overlap (the insert in FIG. 9d), indicating that the Case12/20CdS cubic nanocrystals possess good monodispersity and that the aggregate photoluminescence spectra can reflect their intrinsic photoluminescence properties. Considering the varying degrees of asymmetry observed in all the photoluminescence spectra of the above CdSe, CdS, and CdSe8/yCdS cubic nanocrystals, it indicates that the asymmetry of the photoluminescence spectra is an intrinsic common characteristic of weakly-confined CdE cubic nanocrystals.

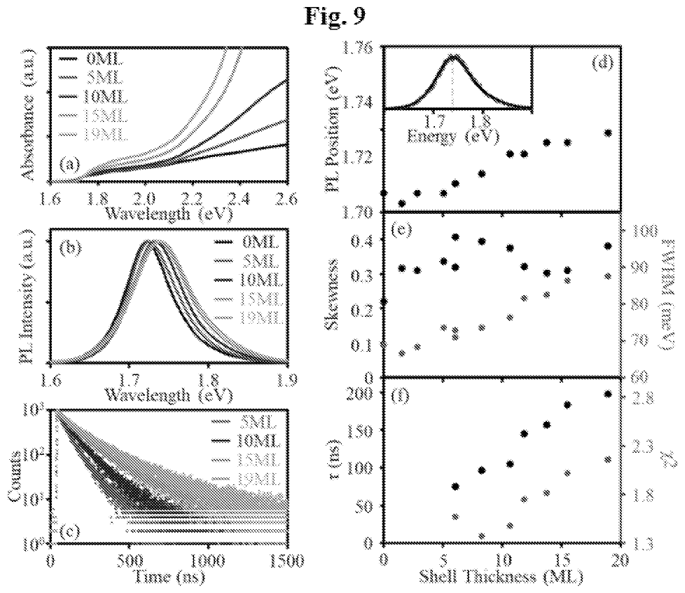

FIG. 9(c) shows transient photoluminescence spectra of CdSe12/yCdS cubic nanocrystals with different CdS shell thicknesses. As the CdS shell thickness increases, the PL lifetime of CdSe12/yCds also gradually increases. Specifically (FIG. 9f), after epitaxially growing 6 layers of CdS shells, the PL lifetime of CdSe12/6CdS reaches around 75 ns, while after epitaxially growing 19 layers of CdS shells, the PL lifetime of CdSe12/19CdS approaches 200 ns. However, as the CdS shell increases, the mono-exponential nature of the transient photoluminescence spectra of CdSe12/CdS cubic nanocrystals noticeably deteriorates. Specifically, after epitaxially growing 19 layers of CdS shells, the goodness of fit χ² of the transient photoluminescence of CdSe12/19CdS approaches 2.0. This indicates the presence of multiple channels during the photoluminescence decay process of CdSe12/19CdS cubic nanocrystals. It is worth noting that for CdSe12/19CdS cubic nanocrystals with a PL lifetime approaching 200 ns, their exciton decay rate exhibits an order of magnitude difference compared to that of the common CdSe3/CdS nanocrystals with a PL lifetime of around 20 ns.

[FIG. 10]

FIG. 10 shows the power-dependent photoluminescence spectra of 15 nm CdSe cubic nanocrystals. As the excitation intensity increases, the corresponding PL intensity continuously enhances. Upon further integral calculations of the photoluminescence spectra, as the excitation power increases from 4 μW to 3430 μW, the linear goodness of fit between PL intensity and excitation power reaches 0.9999. This indicates that within the excitation power range of 4 μW to 3430 μW, the PL emission processes of the 15 min CdSe cubic nanocrystals are all single-exciton emission processes.

During conventional steady-state photoluminescence spectrum measurement (at low excitation power, in the range of tens of μW), one electron in the valence band of the nanocrystal is excited to the conduction band, while creating a hole in the valence band. Then the conduction band electron rapidly relaxes to the conduction-band minimum and recombines with the hole at the valence-band maximum, emitting a photon and generating single-exciton photoluminescence. The single-excitonic PL intensity linearly increases with increasing excitation power. However, at higher excitation powers, multiple photon-induced exciton pairs are generated in the nanocrystals, leading to multi-exciton emission. At this point, the multi-excitonic PL intensity no longer linearly increases with excitation power.

Considering that the excitation power during conventional photoluminescence spectrum measurement is only a few tens of microwatts, the following conclusions can be drawn: For the conventional photoluminescence measurement of the 15 nm CdSe cubic nanocrystals, their photoluminescence spectra are all single-exciton state PL emission spectra, without interference from multi-exciton state emission.

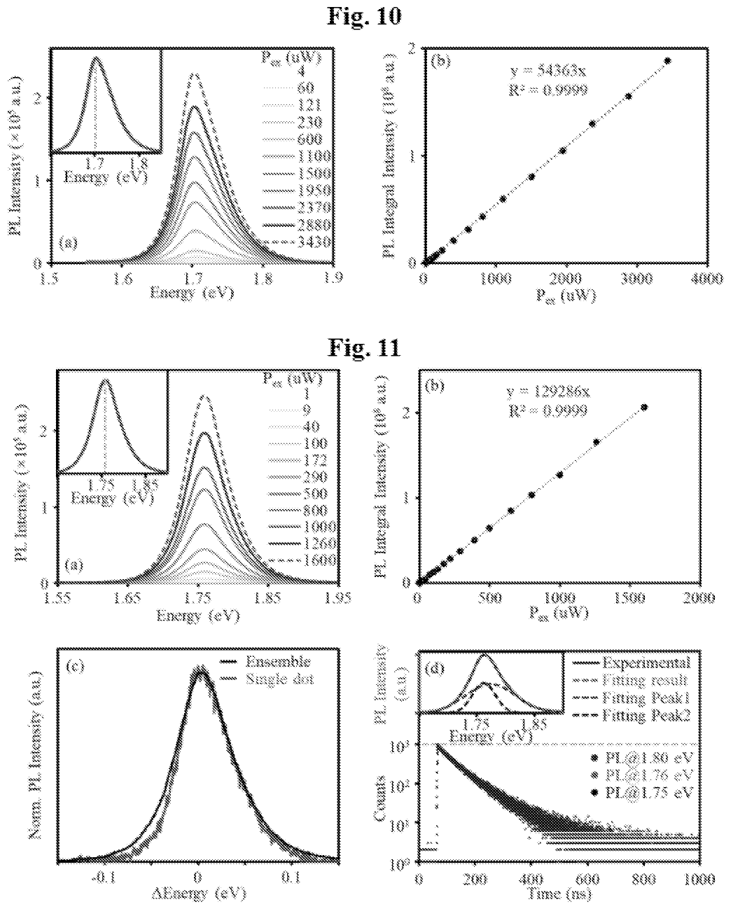

The inset in FIG. 10(a) shows the normalized photoluminescence spectra of CdSe cubic nanocrystals at different powers. The photoluminescence spectra of the CdSe cubic nanocrystals completely overlap and all show a distinct asymmetric feature with a tailing towards higher energy. This indicates that the photoluminescence spectra of CdSe cubic nanocrystals at different powers are characterized by varying photoluminescence intensities, but the shape of the photoluminescence peaks remains largely unchanged. This again demonstrates that within this power range, the double-peak emissions of weakly-confined CdE cubic nanocrystals are all single-exciton state PL emissions.

[FIG. 11]

FIG. 11 shows the power-dependent photoluminescence spectra of CdSe8/20CdS cubic nanocrystals. As the excitation power increases from 1 μW to 1600 μW, the linear goodness of fit between PL intensity and excitation power reaches 0.9999. This indicates that within the excitation power range of 1 μW to 1600 μW, the PL emission processes of the CdSe8/20CdS cubic nanocrystals are all single-exciton emission processes. Considering that the excitation power during conventional photoluminescence spectrum measurement is only a few tens of microwatts, the following conclusions can be drawn: For the conventional photoluminescence measurement of CdSe8/20CdS cubic nanocrystals, their photoluminescence spectra are all single-exciton state PL emission spectra.

The normalized photoluminescence spectra of CdSe8/20CdS cubic nanocrystals at different powers (the inset in FIG. 11a) completely overlap and all show a distinct asymmetric feature with a tailing towards higher energy. This indicates that the photoluminescence spectra of CdSe8/20CdS cubic nanocrystals at different powers are characterized by varying photoluminescence intensities, but the shape of the photoluminescence peaks remains largely unchanged. This again demonstrates the conclusion that within this power range, CdSe8/20CdS cubic nanocrystals are all in the same single-exciton state PL emission.

The single-particle spectrum is a common method for characterizing the intrinsic optical properties of nanocrystals. The aggregate spectrum and the single-particle photoluminescence spectrum of CdSe8/20CdS cubic nanocrystals (FIG. 11c) overlap and both show a distinct asymmetric feature with a tailing towards higher energy. This well demonstrates that the aggregate spectrum of CdSex yCdS cubic nanocrystals with monodisperse size and morphology can truly reflect their intrinsic optical properties, and it demonstrates that the photoluminescence spectrum of CdE cubic nanocrystals with a certain size shows an asymmetric feature.

The photoluminescence spectra of nanocrystals with different charge states are also different, and nanocrystals with different charges exhibit distinct differences in PL lifetimes. FIG. 11(d) shows the transient photoluminescence spectra at different emission positions, revealing no short-lived charge-state emission. The upper part of FIG. 11(d) shows the PL emission spectrum of CdSe8/20CdS cubic nanocrystals and its double-Gaussian fitting result. The perfect fitting result indicates that the apparent asymmetric photoluminescence spectrum may include two PL emission peak positions with different energies. The lower part of FIG. 11(d) shows the transient photolumines cence spectra of the peak positions of the two fitting peaks and the intrinsic photoluminescence spectrum peak. The almost complete overlap of transient photoluminescence spectra indicates that the nanocrystals at different emission positions exhibit no distinct differences in PL lifetimes. That is, the decay rates in the exciton decay process corresponding to the high-energy fitting peak, the apparent photoluminescence peak, and the low-energy fitting peak exhibit no distinct differences. This also rules out the possibility that the asymmetric photoluminescence spectra are caused by nanocrystals being in a charge state.

Through power-dependent experiments on CdSe and CdSe8/20CdS cubic nanocrystals, the possibility of nanocrystals being in a multi-exciton state during conventional photoluminescence testings has been ruled out. By conducting transient photoluminescence testings on CdSe8/20CdS cubic nanocrystals at different emission positions, the possibility of nanocrystals being in a charge state during conventional photoluminescence testings has been ruled out. By comparing single-particle photoluminescence spectra and aggregate photoluminescence spectra of CdSe8/20CdS cubic nanocrystals, the intrinsic nature of the photoluminescence spectrum has been demonstrated. These experimental results well demonstrate that under conventional testing conditions, the aggregate photoluminescence spectrum of CdE cubic nanocrystals with monodisperse size and morphology can reflect their intrinsic photoluminescence spectrum properties, that is, the asymmetry of photoluminescence spectra within a certain size range is an intrinsic characteristic.

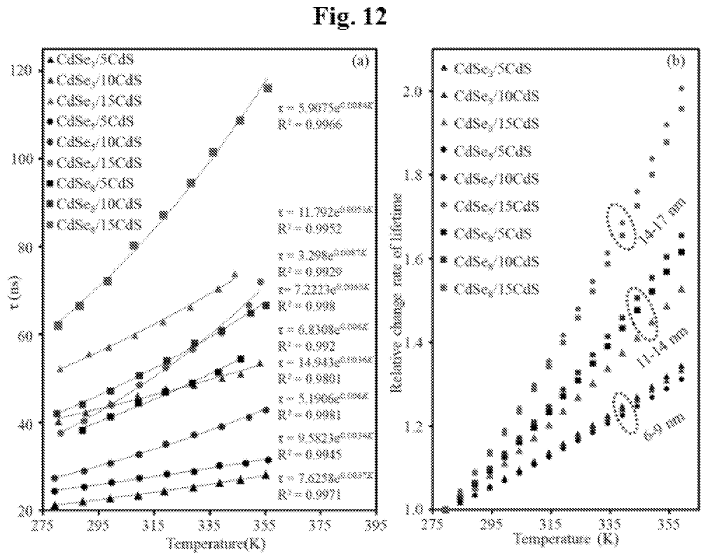

The fitting analysis of the spectra of CdSe and CdS cubic nanocrystals has demonstrated that within a certain size range, the photoluminescence spectra of both CdSe and CdS cubic nanocrystals simultaneously include two exciton state PL emission peak positions. By further combining theoretical energy level calculation results for cubic nanocrystals, the assignment of energy levels for the two exciton states in the photoluminescence spectra is established. The experimental results indicate that CdS and CdSe cubic nanocrystals possess similar size-dependent optical properties, and both possess dual-level emission photoluminescence properties.

[FIG. 12]

FIG. 12 shows the temperature-dependent variations in the PL lifetimes of CdSex yCdS cubic nanocrystals with different-sized CdSe and epitaxially growing CdS of different thicknesses. The PL lifetimes of different types of CdSex yCdS cubic nanocrystals vary with different temperatures. Under the same temperature conditions, considering the extent of exciton confinement effect, the PL lifetime of CdSex/yCdS cubic nanocrystals should generally increase with the increase of nanocrystal size. Taking room temperature as an example, the size-dependent PL lifetimes of CdSex/yCdS cubic nanocrystals in FIG. 12(a) roughly follow this trend. However, the PL lifetimes of CdSe3/10CdS and CdSe3/15CdS do not follow this trend. Specifically, the PL lifetime of CdSe3/10CdS (9 nm) is instead higher than that of CdSe8/10CdS (11 nm) and CdSe5/15CdS (14 mm), and the PL lifetime of CaSe3/15CdS (11 nm) is even higher than that of CdSe8/10CdS (14 nm) and CaSe5/15CdS (14 nm). This indicates that the PL lifetime of CdSex yCdS cubic nanocrystals is not simply proportional to the nanocrystal size. For quasi-type II CdSex/yCdS nanocrystals, the hole wave function is generally effectively confined within the CdSe core, while the electron is delocalized within the entire nanocrystal. The Bohr diameter of the CdSe hole is 2.2 mm. In a 3 mm CdSe core, the hole wave function is effectively confined within the core space range, while in a 5 mm or even larger 8 mm CdSe core, the wave function is no longer subject to significant confinement effects and has a larger space range. Therefore, under the condition of the same space distribution of electronic wave functions (for CdSex yCdS nanocrystals with the same size), the larger the CaSe core size is, the higher the probability of electron-hole recombination radiating photons upon their encounter is, and the shorter the corresponding PL lifetime is.

In another aspect, the rate of change in PL lifetimes for different types of CdSex/yCdS cubic nanocrystals varies with temperature. As shown in FIG. 12(a), when the temperature increases from 280 K to 358 K, the PL lifetime of CdSe3/5CdS only increases from 21 ns to 26 ns, while the PL lifetime of CdSe5/15CdS increases from 37 ns to 72 ns.

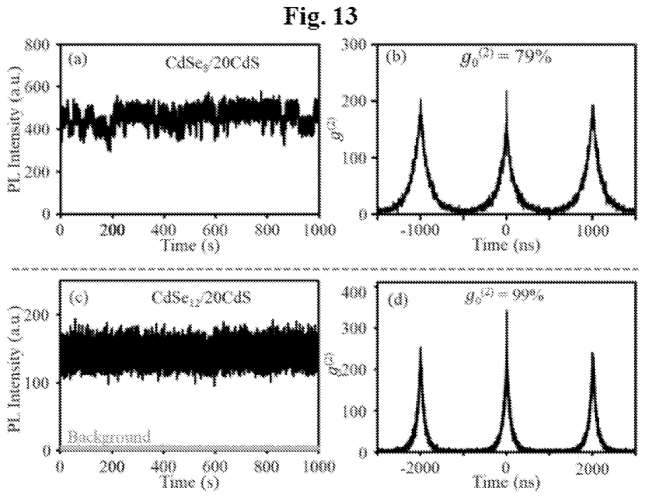

To further compare the rate of change in PL lifetimes for different types of CdSex yCdS cubic nanocrystals with temperature, a common starting temperature (279.15 K) is chosen, and the relative rate of change of the corresponding PL lifetimes is calculated (FIG. 12b). The relative rate of change in lifetime with temperature shows noticeable size dependence. Specifically, within the same temperature range, when the size range of CdSex yCdS cubic nanocrystals is 6-9 nm, the relative rate of change in PL lifetime increases from 1 to around 1.3; when the size range of CdSex/yCdS cubic nanocrystals is 11-14 nm, the relative rate of change in PL lifetime increases from 1 to around 1.6; when the size range of CdSex yCdS cubic nanocrystals is 14-17 nm, the relative rate of change in PL lifetime increases from 1 to around 2. This should be related to the exciton binding energy associated with the CdSex/CdS cubic nanocrystal size. As the CdSex/yCdS cubic nanocrystal size increases, the corresponding confinement effect gradually decreases, and the exciton binding energy gradually decreases. With the increase in temperature, the proportion of electrons and holes present in the form of free carriers in weakly-confined CdSex yCdS cubic nanocrystals increases, so that the rate of change in corresponding PL lifetime with the temperature gradually increases. In FIG. 12(b), three size ranges of CdSex/yCds cubic nanocrystals should correspond to three size ranges with different confinement effects. Compared to CdSe and CdS nanocrystals, where the strength of confinement effects is distinguished directly based on their exciton Bohr radius, the strength of confinement effects in CdSex yCdS cubic nanocrystals can also be distinguished based on the temperature-dependent rate of change in their corresponding PL lifetimes.

[FIG. 13]

As shown in FIG. 13, both CdSe8/20CdS and CdSe12/20CdS exhibit excellent photostability, with the single-particle photoluminescence of CdSe12/20CdS cubic nanocrystals showing no PL blinking phenomenon over up to 1000 seconds. The biexcitonic photoluminescence yield of CdSe8/20CdS reaches 79%, and the biexcitonic photoluminescence yield of CdSe12/20CdS even reaches up to 99%, indicating almost no interference from Auger processes during the biexciton emission. This is highly beneficial for high-power devices (e.g., LEDs, lasers, etc.) whose device efficiency has been constrained by Auger effects. Considering that the corresponding PL lifetimes are in the hundreds of nanosecond range and the regular cubic morphology facilitates dense packing assembly to enhance electron-hole transport rates, weakly-confined CdSex yCdS cubic nanocrystals also hold a great application value in the field of photovoltaics.

The fundamental principles, key features, and advantages of the present invention have been described above. It will be understood by those skilled in the art that the present invention is not limited to the embodiments described above. The embodiments described above and the descriptions in the specification are merely illustrative of the principles of the present invention. Various changes and improvements may be made to the present invention without departing from the spirit and scope of the present invention, and these changes and improvements all fall within the protection scope of the present invention. The protection scope of the present invention is defined by the appended claims and equivalents thereof.

1. A weakly-confined semiconductor nanocrystal, wherein a size of the nanocrystal is larger than an exciton diameter thereof, and the size of the nanocrystal is an average value of a diameter thereof or an average value of a length over centre of mass thereof; under room temperature testing conditions, a double-Gaussian fitting result of PL emission spectra of the nanocrystal shows that the PL emission spectra of the nanocrystal contain two PL emission peak positions with different energies, that is, the nanocrystal possesses dual-level emission photoluminescence properties.

2. A weakly-confined semiconductor nanocrystal, wherein a size of the nanocrystal is larger than an exciton diameter thereof, and the size of the nanocrystal is an average value of a diameter thereof or an average value of a length over centre of mass thereof; a biexcitonic photoluminescence quantum yield of the nanocrystal is not less than 50%.

3. The weakly-confined semiconductor nanocrystal according to claim 2, wherein the size of the nanocrystal is 1 to 20 times the exciton diameter thereof.

4. The weakly-confined semiconductor nanocrystal according to claim 2, wherein the size of the nanocrystal is greater than 10 nm.

5. The weakly-confined semiconductor nanocrystal according to claim 2, wherein a relative standard deviation of a size distribution of the nanocrystal does not exceed 10%.

6. The weakly-confined semiconductor nanocrystal according to claim 2, wherein the nanocrystal is either a core-structured nanocrystal or a core-shell structured nanocrystal.

7. The weakly-confined semiconductor nanocrystal according to claim 2, wherein the nanocrystal is a cubic nanocrystal, a transmission electron microscope image shows that the nanocrystal has a square two-dimensional projection, and a high-resolution transmission electron microscope image shows that the nanocrystal has lattice fringes of single-period and dislocation-free and atomically smooth boundaries.

8. The weakly-confined semiconductor nanocrystal according to claim 2, wherein the nanocrystal is a CdS or CdSe or CdSe/CdS core/shell cubic nanocrystal, a CdSe core size of the CdSe CdS core/shell cubic nanocrystal ranges from 6 nm to 25 mm, and a number of layers of CdS shell ranges from 1 to 20 monolayers.

9. The weakly-confined semiconductor nanocrystal according to claim 2, wherein the nanocrystal is an II-IV group semiconductor or an III-V group semiconductor.

10. The weakly-confined semiconductor nanocrystal according to claim 2, wherein the nanocrystal has a zinc-blende single-crystal structure.

11. The weakly-confined semiconductor nanocrystal according to claim 2, wherein excitation spectra of the nanocrystal at different fluorescent emission positions substantially overlap.

12. The weakly-confined semiconductor nanocrystal according to claim 2, wherein a PL emission peak position of the nanocrystal is substantially consistent with a bandgap width of a bulk material thereof.

13. The weakly-confined semiconductor nanocrystal according to claim 2, wherein excitons in the nanocrystal are dynamic excitons, at operating temperatures, electron-hole Coulomb interaction of the dynamic excitons is insufficient to bind electrons and holes into stable bound excitons, the electrons and the holes of the dynamic excitons are constrained by boundaries of the nanocrystal, and the operating temperatures include room temperature.

14. The weakly-confined semiconductor nanocrystal according to claim 2, wherein under room temperature testing conditions, a UV-Visible absorption spectrum of the nanocrystal exhibits a quasi-continuous band absorption.

15. The weakly-confined semiconductor nanocrystal according to claim 2, wherein under room temperature testing conditions, a photoluminescence spectrum of the nanocrystal shows an asymmetric feature with a tailing towards higher energy.

16. A method for preparing a weakly-confined semiconductor nanocrystal, comprising the following steps:
synthesis of a nanocrystal seed: reacting a cationic precursor with a first fatty acid at a first temperature, and then adding a first anionic precursor for reacting to obtain a nanocrystal seed, a size of the nanocrystal seed being smaller than an exciton diameter thereof, and the size of the nanocrystal seed being an average value of a diameter thereof or an average value of a length over centre of mass thereof; and
growth of a nanocrystal: reacting a cationic precursor, a first fatty acid, a second fatty acid, and a fatty acid chloride at a second temperature, and then sequentially adding the nanocrystal seed and a second anionic precursor for growth to obtain a nanocrystal, a size of the nanocrystal being not less than an exciton diameter thereof, and the size of the nanocrystal being an average value of a diameter thereof or an average value of a length over centre of mass thereof.

17. The method for preparing a weakly-confined semiconductor nanocrystal according to claim 16, wherein the first fatty acid is a fatty acid with a carbon chain length of no less than 10, preferably a fatty acid with a carbon chain length of no more than 18.

18. The method for preparing a weakly-confined semiconductor nanocrystal according to claim 16, wherein the second fatty acid is a fatty acid with a carbon chain length of no less than 22.

19. The method for preparing a weakly-confined semiconductor nanocrystals according to claim 16, wherein the cationic precursor is cadmium carboxylate, and the first anionic precursor is either a selenium (Se) precursor or a sulfur (S) precursor.

20. Use of the weakly-confined semiconductor nanocrystal according to claim 2, wherein the weakly-confined semiconductor nanocrystal is used in illumination or display, photovoltaic solar devices, photoelectric detectors, lasers, quantum light sources, or photochemical catalysis.
